(19) United States
(12) Patent Application Publication
(10) Pub. No.: US 2017/0058079 A1
(43) Pub. Date: Mar. 2, 2017

(54) POLYMER COMPOUND, RADIATION SENSITIVE COMPOSITION AND PATTERN FORMING METHOD

(71) Applicants: A School Corporation Kansai University, Osaka (JP); Mitsubishi Gas Chemical Company, Inc., Tokyo (JP)

(72) Inventors: Hiroto KUDO, Osaka (JP); Masatoshi ECHIGO, Tokyo (JP); Takumi TOIDA, Hiratsuka-shi (JP); Takashi SATO, Hiratsuka-shi (JP)

(21) Appl. No.: 15/151,131

(22) Filed: May 10, 2016

(30) Foreign Application Priority Data
Aug. 24, 2015 (JP) 2015-165308
Nov. 10, 2015 (JP) 2015-220610
Apr. 28, 2016 (JP) 2016-091799

(51) Int. Cl. C08G 63/668; G03F 7/32; G03F 7/20; G03F 7/038; G03F 7/16

(52) U.S. Cl. CPC C08G 63/668; G03F 7/0382; G03F 7/16; G03F 7/2059; G03F 7/325

(57) ABSTRACT

A polymer compound including a unit structure represented by the general formula (1):

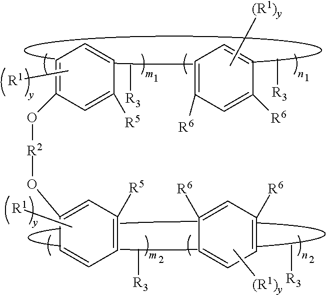

wherein m₁ and m₂ each equal 1 to 8, n₁ and n₂ each equal 0 to 7, m₁+n₁ and m₂+n₂ each equal 4 to 8, y represents 0 to 2, R¹ represents a hydroxy group; a substituted or unsubstituted straight, branched or cyclic alkyl group; a substituted or unsubstituted aryl group, or a halogen atom, R³ represents a hydrogen atom, a substituted or unsubstituted straight, branched or cyclic alkyl group, or a substituted or unsubstituted aryl group, R² represents any structure represented by general formula (2) in the specification, at least one R² has an acid-dissociable site, R⁵ represents a hydroxy group, —O—R²—O—* or —O—R²—O—R⁵⁵, and R⁶ represents a hydroxy group or —O—R²—O—*.

### CROSS REFERENCE TO RELATED APPLICATIONS

This application claims priority to Japanese Patent Applications Nos. JP2015-165308 filed on Aug. 24, 2015, JP2015-220610 filed on Nov. 10, 2015 and JP2016-91799 filed on Apr. 28, 2016, the entire contents of which are incorporated by reference herein.

### BACKGROUND OF THE INVENTION

Field of the Invention

The present invention relates to a polymer compound, and a radiation sensitive composition and a resist pattern forming method using the same.

Description of the Related Art

In accordance with miniaturization of a semiconductor device, the development of a lithography process using, for example, extreme ultraviolet light (13.5 nm) or an electron beam has been actively advanced. As a base material serving as a base of a chemically amplified positive resist coping with such a process, a novolac-based phenolic resin, a polyhydroxystyrene-based resin and a (meth)acrylic acid-based resin, which are polymer-based resist materials, have been mainly studied. Such a polymer-based resist material, however, has a high molecular weight of about 10000 to 100000, and also has a broad molecular weight distribution. Therefore, lithography in which such a polymer-based resist material is used has the problem of causing roughness on a fine pattern surface. Then, a compound has been actively developed in recent years, in which an acid-dissociable functional group that is decomposed by the action of an acid is introduced to a polyphenol-based compound or a calixarene-based compound which is a low-molecular resist material, and an example has also been reported in which roughness of a fine pattern is reduced as compared with the case of the polymer-based resist material. In addition, the calixarene-based compound for use as the low-molecular resist material has a rigid cyclic structure in a main backbone and thus has a sufficient heat resistance required for pattern formation, and therefore is viewed as promising.

For the acid-dissociable functional group, monofunctional alkoxymethyl, alkoxyethyl and tertiary alkoxy groups are mainly used (see, for example, Japanese Patent Laid-Open No. 2009-173623 (Patent Literature 1)).

For the purposes of reducing roughness of a pattern obtained using a polymer-based material and suppressing collapse of the pattern, the use of a multifunctional acid-dissociable functional group is also actively studied (see, for example, Japanese Patent Laid-Open No. 11-344808 (Patent Literature 2), Japanese Patent Laid-Open No. 2000-098613 (Patent Literature 3), Japanese Patent Laid-Open No. 2005-308977 (Patent Literature 4), Japanese Patent Laid-Open No. 2006-2073 (Patent Literature 5), Japanese Patent Laid-Open No. 2006-3846 (Patent Literature 6), Japanese Patent Laid-Open No. 2007-206371 (Patent Literature 7)).

A main-chain cleavage positive resist material is proposed which is obtained by reacting a multifunctional acid-dissociable functional group with a calixarene-based compound having a rigid cyclic structure (see, for example, International Publication No. 2012/014435 (Patent Literature 8)).

### CITATION LIST

### Patent Literatures

Patent Literature 1: Japanese Patent Laid-Open No. 2009-173623

Patent Literature 2: Japanese Patent Laid-Open No. 11-344808

Patent Literature 3: Japanese Patent Laid-Open No. 2000-098613

Patent Literature 4: Japanese Patent Laid-Open No. 2005-308977

Patent Literature 5: Japanese Patent Laid-Open No. 2006-2073

Patent Literature 6: Japanese Patent Laid-Open No. 2006-3846

Patent Literature 7: Japanese Patent Laid-Open No. 2007-206371

Patent Literature 8: International Publication No. 2012/014435

### SUMMARY OF THE INVENTION

The compound to which the acid-dissociable functional group is introduced, described in Patent Literature 1, however, has the problem of causing collapse of the resulting fine pattern to easily occur. The resist material described in Patent Literature 8 has a limit on resolution, and has room for improvement from such a viewpoint.

An object of the present invention is to provide a polymer compound that achieves a high sensitivity and that provides a fine pattern, a radiation sensitive composition including the compound, and a pattern forming method using the same.

The present inventors have made intensive studies in order to solve the above problems, and as a result, have found that the above problems are solved by a polymer having a specific structure, leading to completion of the present invention.

That is, the present invention is as follows.

<1> A polymer compound including a unit structure represented by the following general formula (1):

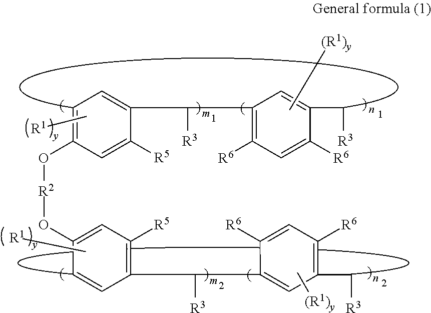

wherein in the general formula (1), m₁ represents an integer of 1 to 8, n₁ represents an integer of 0 to 7, m₁+n₁ equals an integer of 4 to 8, m₂ represents an integer of 1 to 8, n₂ represents an integer of 0 to 7, m₂+n₂ equals an integer of 4 to 8, each y independently represents an integer of 0 to 2, each R¹ independently represents a hydroxy group; a substituted or unsubstituted, straight, branched or cyclic alkyl group having 1 to 20 carbon atoms, 3 to 20 carbon atoms or 3 to 20 carbon atoms, respectively; a substituted or unsubstituted aryl group having 6 to 20 carbon atoms; or a halogen atom, each R³ independently represents a hydrogen atom; a substituted or unsubstituted, straight, branched or cyclic alkyl group having 1 to 20 carbon atoms, 3 to 20 carbon atoms or 3 to 20 carbon atoms, respectively; or a substituted or unsubstituted aryl group having 6 to 20 carbon atoms, each R² independently represents any structure represented by the following general formula (2), provided that at least one R² has an acid-dissociable site, R⁵ represents a hydroxy group, —O—R²—O—* (* represents a binding site of the unit structure) or —O—R²—O—R⁵⁵ (R⁵⁵ represents other R⁵ in the general formula (1)), and R⁶ represents a hydroxy group or —O—R²—O—* (* represents a binding site of the unit structure);

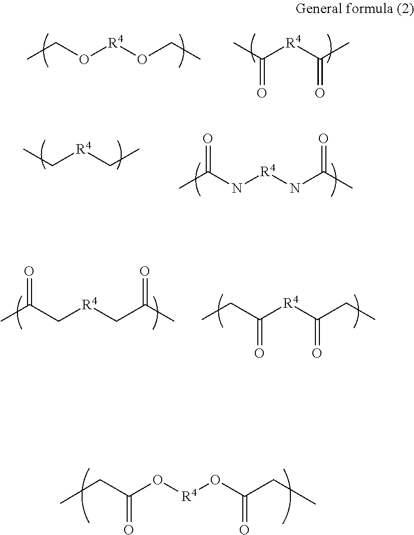

wherein in the general formula (2), R⁴ represents a substituted or unsubstituted straight, branched or cyclic alkylene group having 1 to 20 carbon atoms, 3 to 20 carbon atoms or 3 to 20 carbon atoms, respectively; or a substituted or unsubstituted arylene group having 6 to 20 carbon atoms.

<2> The polymer compound according to <1>, wherein in the general formula (1), R³ represents a substituted or unsubstituted, straight, branched or cyclic alkyl group having 1 to 10 carbon atoms, 3 to 20 carbon atoms or 3 to 20 carbon atoms, respectively; or a substituted or unsubstituted aryl group having 6 to 10 carbon atoms.

<3> A radiation sensitive composition including the polymer compound according to <1> or <2>.

<4> The radiation sensitive composition according to <3>, further including a solvent.

<5> A pattern forming method including forming a film on a substrate by use of the radiation sensitive composition according to <3> or <4>, exposing the film, and developing the film exposed to form a pattern.

The present invention can provide a polymer compound that achieves a high sensitivity and that provides a fine pattern, a resist material and a radiation sensitive composition including the compound, and a resist pattern forming method using the compound.

### BRIEF DESCRIPTION OF THE DRAWINGS

FIG. 1 is a diagram illustrating a ¹H-NMR spectrum of a compound obtained in Example 1; and

FIG. 2 is a diagram illustrating an IR spectrum of the compound obtained in Example 1.

### DETAILED DESCRIPTION OF THE PREFERRED EMBODIMENT

Hereinafter, an embodiment of the present invention is described (hereinafter, sometimes referred to as “the present embodiment”). Herein, the present embodiment is illustrative for describing the present invention, and the present invention is not limited to only the present embodiment.

### (Polymer Compound)

A polymer compound of the present embodiment is a polymer including a unit structure represented by the following general formula (1):

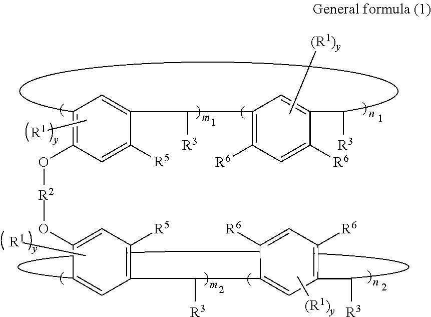

wherein in the general formula (1), m₁ represents an integer of 1 to 8, n₁ represents an integer of 0 to 7, m₁+n₁ equals an integer of 4 to 8, m₂ represents an integer of 1 to 8, n₂ represents an integer of 0 to 7, m₂+n₂ equals an integer of 4 to 8, each y independently represents an integer of 0 to 2, each R¹ independently represents a hydroxy group; a substituted or unsubstituted, straight, branched or cyclic alkyl group having 1 to 20 carbon atoms, 3 to 20 carbon atoms or 3 to 20 carbon atoms, respectively; a substituted or unsubstituted aryl group having 6 to 20 carbon atoms; or a halogen atom, each R³ independently represents a hydrogen atom; a substituted or unsubstituted, straight, branched or cyclic alkyl group having 1 to 20 carbon atoms, 3 to 20 carbon atoms or 3 to 20 carbon atoms, respectively; or a substituted or unsubstituted aryl group having 6 to 20 carbon atoms, each R² independently represents any structure represented by the following general formula (2), provided that at least one R² has an acid-dissociable site, R⁵ represents a hydroxy group, —O—R²—O—* (* represents a binding site of the unit structure) or —O—R²—O—R⁵⁵ (R⁵⁵ represents other R⁵ in the general formula (1)), and R⁶ represents a hydroxy group or —O—R²—O—* (* represents a binding site of the unit structure);

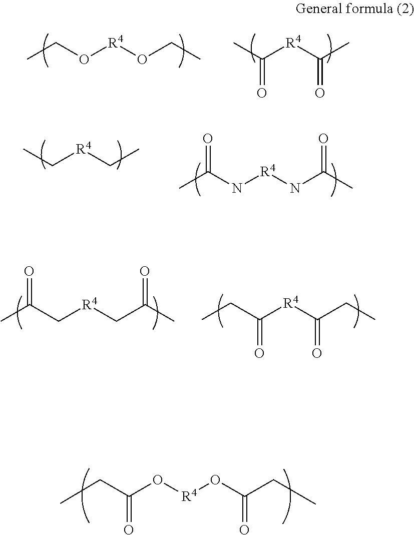

wherein in the general formula (2), R⁴ represents a substituted or unsubstituted straight, branched or cyclic alkylene group having 1 to 20 carbon atoms, 3 to 20 carbon atoms or 3 to 20 carbon atoms, respectively; or a substituted or unsubstituted arylene group having 6 to 20 carbon atoms.

The polymer compound of the present embodiment can have a specific structure as described above to provide a high sensitivity, and to provide a fine pattern when used in a radiation sensitive composition. Furthermore, the polymer compound of the present embodiment can be if necessary increased in solubility in a safe solvent, and can allow production to be easily controlled and allow the quality to be stabilized.

First, the structure of the polymer compound of the present embodiment is described. As illustrated below, the polymer compound of the present embodiment includes a unit structure (“C” below) represented by general formula (1). The unit structure represented by the general formula (1) included in the polymer compound of the present embodiment is not particularly limited in the number thereof, and the number is preferably 1 to 100 in terms of resolution, further preferably 1 to 50 in terms of roughness, particularly preferably 1 to 10 in terms of sensitivity. When the polymer compound of the present embodiment has a plurality of the unit structures, such unit structures are bonded to each other via “—O—R²—O—*” in R⁵ or R⁶ in the general formula (1). That is, when the polymer compound of the present embodiment has a plurality of the unit structures, the structural unit represented by the general formula (1) has —O—R²—O—* as R⁵ or R⁶. The polymer compound of the present embodiment can include a constitutional unit other than the unit structure represented by the general formula (1) as long as the effect of the present invention is not impaired. Examples of the unit structure other than the unit structure represented by the general formula (1) include a structure including only an upper or lower cyclic structure described later. The polymer compound of the present embodiment may be constituted from only the same unit structure, or may include two or more constitutional units.

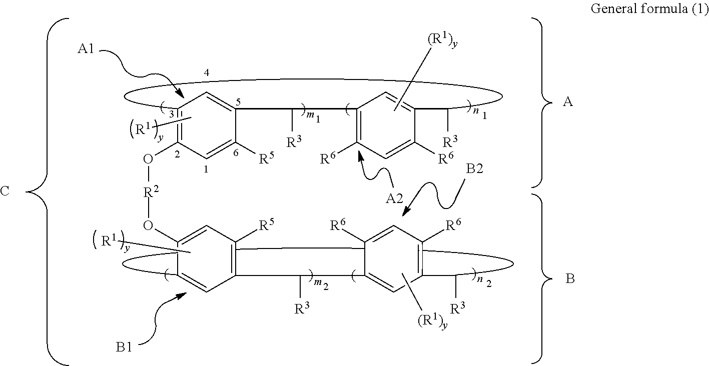

The unit structure in the polymer compound of the present embodiment is constituted by including two cyclic structures. For convenience, a cyclic structure positioned upward in the general formula (1) herein refers to an “upper cyclic structure” (“A” above), and a cyclic structure positioned downward in the general formula (1) herein refers to a “lower cyclic structure” (“B” above), provided that the upper cyclic structure and the lower cyclic structure are not distinguished from each other in the actual compound. Each of the cyclic structures has two benzene ring structures. For example, the upper cyclic structure includes a benzene ring structure (“A1” above) having a site bonded to the lower cyclic structure and R⁵, and a benzene ring structure (“A2” above) having R⁶. Similarly, the lower cyclic structure includes a benzene ring structure (“B1” above) having a site bonded to the upper cyclic structure and R⁵, and a benzene structure (“B2” above) having R⁶. Herein, such structures are appropriately referred to as “benzene ring structures A1 to B2”.

In the polymer compound of the present embodiment, each of the upper cyclic structure and the lower cyclic structure forms one cyclic structure by bonding of the respective benzene ring structures. That is, a number m₁ of the benzene ring structures A1 and a number n₁ of the benzene ring structures A2 are bonded to form the upper cyclic structure. Similarly, the lower cyclic structure is constituted from a number m₂ of the benzene ring structures B1 and a number n₂ of the benzene ring structures B2. In such cases, any arrangement of a number m₁ of the benzene ring structures A1 and a number n₁ of the benzene ring structures A2 in the upper cyclic structure, and any arrangement of a number m₂ of the benzene ring structures B1 and a number n₂ of the benzene ring structures B2 in the lower cyclic structure can be taken, and such arrangements may be regular or may be random.

In the general formula (1), m₁ represents an integer of 1 to 8, n₁ represents an integer of 0 to 7 and m₁+n₁ equals an integer of 4 to 8, and m₁ preferably represents an integer of 2 to 6, n₁ preferably represents an integer of 2 to 6 and m₁+n₁ preferably equals an integer of 2 to 8, but not particularly limited.

In the general formula (1), m₂ represents an integer of 1 to 8, n₂ represents an integer of 0 to 7 and m₂+n₂ equals an integer of 4 to 8, and m₂ preferably represents an integer of 2 to 6, n₂ preferably represents an integer of 2 to 6 and m₁+n₁ preferably equals an integer of 2 to 8, but not particularly limited.

Herein, when the polymer compound of the present embodiment includes a plurality of the constitutional units represented by the general formula (1), m₁, m₂, n₁ and n₂ in each of the constitutional units may be the same or may be different.

For example, in the upper cyclic structure, carbon at the 3-position and carbon at the 5-position of the benzene rings in the benzene ring structures A1 and A2, respectively, can serve as bonding sites for constituting the upper cyclic structure. Much the same is true on the benzene ring structures B1 and B2 in the lower cyclic structure.

Each R¹ independently represents a hydroxy group; a substituted or unsubstituted, straight, branched or cyclic alkyl group having 1 to 20 carbon atoms, 3 to 20 carbon atoms or 3 to 20 carbon atoms, respectively (namely, a substituted or unsubstituted straight alkyl group having 1 to 20 carbon atoms, a substituted or unsubstituted branched alkyl group having 3 to 20 carbon atoms and a substituted or unsubstituted cyclic alkyl group having 3 to 20 carbon atoms); a substituted or unsubstituted aryl group having 6 to 20 carbon atoms; or a halogen atom. In addition, each y independently represents an integer of 0 to 2.

Examples of the unsubstituted straight alkyl group having 1 to 20 carbon atoms include a methyl group, an ethyl group, a propyl group, a butyl group, a pentyl group, a hexyl group, an octyl group, a decyl group, a dodecyl group, a hexadecyl group and an octadecyl group.

Examples of the substituted straight alkyl group having 1 to 20 carbon atoms include a fluoromethyl group, a 2-hydroxyethyl group, a 3-cyanopropyl group and a 20-nitrooctadecyl group.

A substituted or unsubstituted straight alkyl group having 1 to 10 carbon atoms can be preferably used as the substituted or unsubstituted straight alkyl group.

Examples of the unsubstituted branched alkyl group having 3 to 20 carbon atoms include an isopropyl group, an isobutyl group, a tert-butyl group, a neopentyl group, a 2-hexyl group, a 2-octyl group, a 2-decyl group, a 2-dodecyl group, a 2-hexadecyl group and a 2-octadecyl group.

Examples of the substituted branched alkyl group having 3 to 20 carbon atoms include a 1-fluoroisopropyl group and a 1-hydroxy-2-octadecyl group.

Examples of the unsubstituted cyclic alkyl group having 3 to 20 carbon atoms include a cyclopropyl group, a cyclobutyl group, a cyclopentyl group, a cyclohexyl group, a cyclooctyl group, a cyclodecyl group, a cyclododecyl group, a cyclohexadecyl group and a cyclooctadecyl group.

Examples of the substituted cyclic alkyl group having 3 to 20 carbon atoms include a 2-fluorocyclopropyl group and a 4-cyanocyclohexyl group.

Examples of the unsubstituted aryl group having 6 to 20 carbon atoms include a phenyl group and a naphthyl group.

Examples of the substituted aryl group having 6 to 20 carbon atoms include a 4-isopropylphenyl group, a 4-cyclohexylphenyl group, a 4-methylphenyl group and a 6-fluoronaphthyl group. One having 6 to 10 carbon atoms can be preferably used as the substituted or unsubstituted aryl group.

Examples of the halogen atom include a fluorine atom, a chlorine atom, a bromine atom and an iodine atom.

Herein, the term “substituted” means, unless otherwise defined, that at least one hydrogen atom in a functional group is substituted with a halogen atom, a hydroxy group, a cyano group, a nitro group, a heterocyclic group, a straight aliphatic hydrocarbon group having 1 to 20 carbon atoms, a branched aliphatic hydrocarbon group having 3 to 20 carbon atoms, an alicyclic hydrocarbon group having 3 to 20 carbon atoms, an aryl group having 6 to 20 carbon atoms, an aralkyl group having 7 to 30 carbon atoms, an alkoxy group having 1 to 20 carbon atoms, an amino group having 0 to 20 carbon atoms, an alkenyl group having 2 to 20 carbon atoms, an acyl group having 1 to 20 carbon atoms, an alkoxycarbonyl group having 2 to 20 carbon atoms, an alkyloyloxy group having 1 to 20 carbon atoms, an aryloyloxy group having 7 to 30 carbon atoms or an alkylsilyl group having 1 to 20 carbon atoms.

In the general formula (1), each R³ independently represents a hydrogen atom, a substituted or unsubstituted, straight, branched or cyclic alkyl group having 1 to 20 carbon atoms, 3 to 20 carbon atoms or 3 to 20 carbon atoms, respectively, or a substituted or unsubstituted aryl group having 6 to 20 carbon atoms.

In R³, examples of the substituted or unsubstituted, straight, branched or cyclic alkyl group having 1 to 20 carbon atoms, 3 to 20 carbon atoms or 3 to 20 carbon atoms, respectively; and the substituted or unsubstituted aryl group having 6 to 20 carbon atoms include the same as exemplified in R¹.

In the general formula (1), each R² independently represents any structure represented by the general formula (2), provided that at least one R² has an acid-dissociable site. R² can have an acid-dissociable site to thereby allow the polymer compound to function as a main-chain cleavage positive resist material or negative resist material, where a polymer is cleaved by the action of an acid.

In the general formula (2), R⁴ represents a substituted or unsubstituted straight, branched or cyclic alkylene group having 1 to 20 carbon atoms, 3 to 20 carbon atoms or 3 to 20 carbon atoms, respectively; or a substituted or unsubstituted arylene group having 6 to 20 carbon atoms.

Examples of the unsubstituted straight alkylene group having 1 to 20 carbon atoms include a methylene group, an ethylene group, a propylene group, a butylene group, a pentylene group, a hexylene group, an octylene group, a decylene group, a dodecylene group, a hexadecylene group and an octadecylene group.

Examples of the unsubstituted straight alkylene group having 1 to 20 carbon atoms include a fluoromethylene group, a 2-hydroxyethylene group, a 3-cyanopropylene group and a 20-nitrooctadecylene group.

Examples of the unsubstituted branched alkylene group having 3 to 20 carbon atoms include an isopropylene group, an isobutylene group, a tert-butylene group, a neopentylene group, a 2-hexylene group, a 2-octylene group, a 2-decylene group, a 2-dodecylene group, a 2-hexadecylene group and a 2-octadecylene group.

Examples of the unsubstituted branched alkylene group having 3 to 20 carbon atoms include a 1-fluoroisopropylene group and a 1-hydroxy-2-octadecylene group.

Examples of the unsubstituted cyclic alkylene group having 3 to 20 carbon atoms include a cyclopropylene group, a cyclobutylene group, a cyclopentylene group, a cyclohexylene group, a cyclooctylene group, a cyclodecylene group, a cyclododecylene group, a cyclohexadecylene group and a cyclooctadecylene group.

Examples of the substituted cyclic alkylene group having 3 to 20 carbon atoms include a 2-fluorocyclopropylene group and a 4-cyanocyclohexylene group.

Examples of the unsubstituted arylene group having 6 to 20 carbon atoms include a phenylene group and a naphthylene group.

Examples of the substituted arylene group having 6 to 20 carbon atoms include a 4-isopropylphenylene group, a 4-cyclohexylphenylene group, a 4-methylphenylene group and a 6-fluoronaphthylene group.

In the general formula (1), at least one R² has an acid-dissociable site. Herein, the term “acid-dissociable site” refers to a site that is cleaved in the presence of an acid to result in the change of an alkali soluble group or the like. The alkali soluble group is not particularly limited, and examples include a phenolic hydroxy group, a carboxyl group, a sulfonic acid group and a hexafluoroisopropanol group. A phenolic hydroxy group and a carboxyl group are preferable, and a phenolic hydroxy group is particularly preferable. Examples of the general formula (2) having the acid-dissociable site include the following.

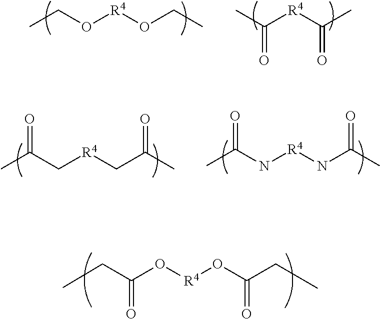

R⁵ in the general formula (1) represents a hydroxy group, —O—R²—O—* (* represents a binding site of the unit structures) or —O—R²—O—R⁵⁵ (R⁵⁵ represents other R⁵ in the general formula (1)). That is, in the benzene ring structures A1 and B1, the upper cyclic structure and the lower cyclic structure in the same unit structure are bonded by at least one “—O—R²—O—” on the benzene ring. The other bond of the benzene ring structures A1 and B1 (namely, R⁵) may be a hydroxy group (OH—), may be “—O—R²—O—*” bonded to other unit structure at “*”, or may be “—O—R²—O—R⁵” and bonded to other R⁵ in the upper cyclic structure or the lower cyclic structure in the same unit structure to bond the upper cyclic structure and the lower cyclic structure in the same unit structure.

R⁶ in the general formula (1) represents a hydroxy group or —O—R²—O—* (* represents a binding site of the unit structures).

As described above, when the polymer compound of the present embodiment has a plurality of the unit structures, at least one of R⁵ and R⁶ in at least one of the unit structures represented by the general formula (1) represents “—O—R²—O—*” and the plurality of the unit structures are bonded via such R⁵ or R⁶. In —O—R²—O—*, “*” represents a binding site of the unit structures. For example, when the polymer compound of the present embodiment has two of the unit structures represented by the general formula (1), a * portion of at least one (—O—R²—O—*) of R⁵ and R⁶ in one of the unit structures represented by the general formula (1) is bonded to a carbon atom constituting the benzene ring in the other of the unit structures represented by the general formula (1).

When R⁵ in the general formula (1) represents “—O—R²—O—R⁵⁵”, namely, one benzene ring structure A1 or B1 has two “—O—R²—O—” that bonds the upper cyclic structure to the lower cyclic structure, such two “—O—R²—O—” may be each bonded to other different benzene ring structure, or may be bonded to the same benzene ring structure.

Furthermore, when a plurality of R⁵ and/or R⁶ have “—O—R²—O—*”, R⁵ and/or R⁶ may be bonded to the same other unit structure or may each be bonded to other different unit structure, via “—O—R²—O—*”.

The polymer compound of the present embodiment can be obtained by reacting, for example, a compound represented by the following general formula (3) with any compound of a group represented by the following general formula (4).

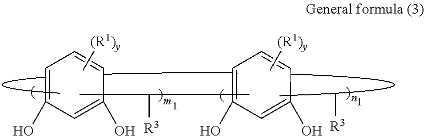

In the general formula (3), R¹, R³, m₁, n₁ and y have the same meaning as defined in the general formula (1).

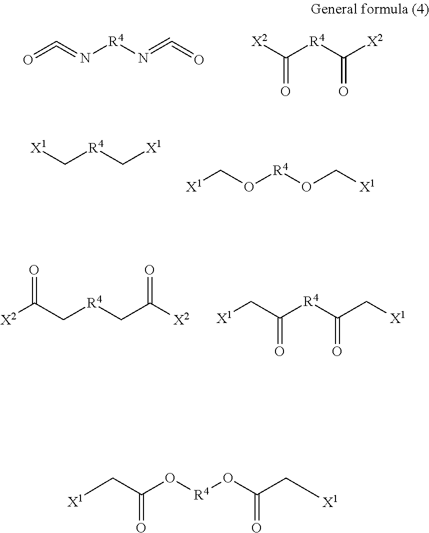

In the general formula (4), R⁴ has the same meaning as defined in the general formula (2), X¹ represents a halogen atom, and X² represents a halogen atom or a hydroxy group.

The halogen atom represented by each of X¹ and X² in the general formula (4) includes the same as recited in R¹ above.

The compound represented by the formula (3) preferably includes one compound selected from the group consisting of compounds shown below.

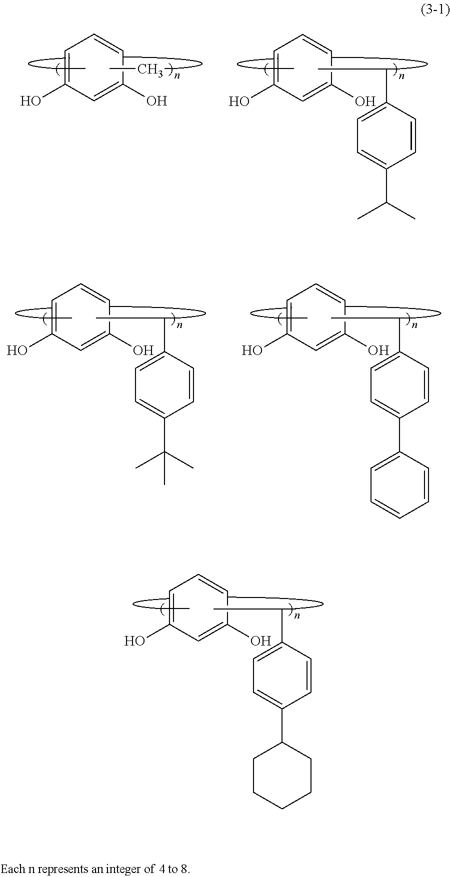

The compound represented by the formula (4) preferably includes one compound selected from the group consisting of compounds shown below.

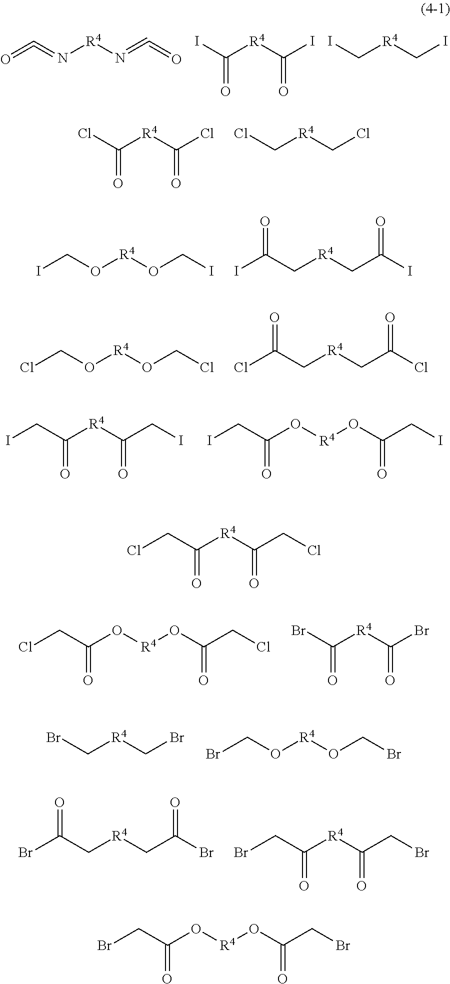

In the formula (4-1), R⁴ has the same meaning as defined in the general formula (2).

R⁴ described above preferably includes one group selected from the group represented by the following formula (4-2), in terms of heat resistance.

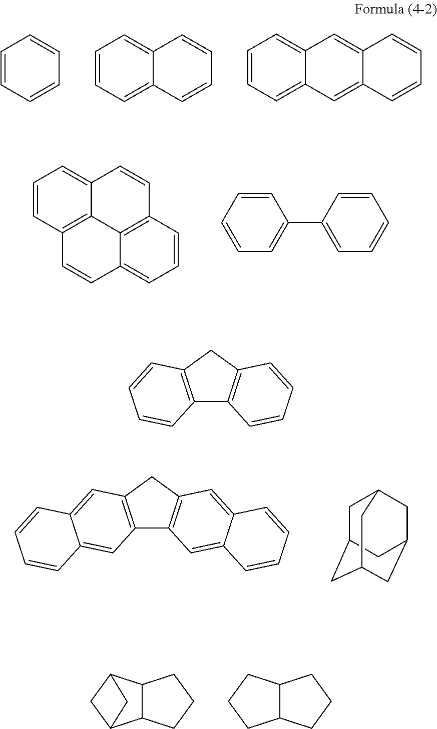

The reaction of the compound represented by the general formula (3) with any compound of the group represented by the general formula (4) is not particularly limited, and preferably, both the compounds are if necessary dissolved in a solvent and reacted in the presence of a catalyst.

Examples of the solvent for use in the reaction of the compound represented by the general formula (3) with any compound of the group represented by the general formula (4) include aprotic solvents such as acetone, tetrahydrofuran (THF), propylene glycol monomethyl ether acetate, dimethyl acetamide and N-methylpyrrolidone. For example, the compound represented by the general formula (3) is dissolved or suspended in such a solvent. Subsequently, a divinyl alkyl ether (compound represented by the general formula (4)) such as divinyloxy methyl adamantane is added thereto and the resultant is subjected to the reaction in the presence of an acid catalyst such as trifluoroacetic acid or pyridinium p-toluenesulfonate at an ordinary pressure and at 20 to 60° C. for 6 to 72 hours. The reaction liquid is neutralized by an alkali compound and added to distilled water to precipitate a white solid, and thereafter the white solid separated is washed with distilled water and dried to thereby provide an intended polymer compound.

For example, the compound represented by the general formula (3) is dissolved or suspended in an aprotic solvent, subsequently an alkyl halide such as ethyl chloromethyl ether (compound represented by the general formula (4)) is added thereto, and the resultant is subjected to the reaction in the presence of an alkali catalyst such as potassium carbonate at an ordinary pressure and at 20 to 110° C. for 6 to 72 hours. The reaction liquid is neutralized by an acid such as hydrochloric acid and added to distilled water to precipitate a white solid, and thereafter the white solid separated is washed with distilled water and dried to thereby provide an intended polymer compound.

In the present embodiment, the polymer compound is preferably synthesized using two or more of the compounds represented by the general formula (3) and/or any compounds of the group represented by the general formula (4). Two or more of the compounds represented by the general formula (3) and/or any compounds of the group represented by the general formula (4) are used to thereby result in an enhancement in the solubility of the resulting polymer in a semiconductor safe solvent.

In order to reduce the amount of a metal remaining in the polymer, the polymer may also be if necessary subjected to a purification treatment. If the acid catalyst remains, a radiation sensitive composition deteriorated in storage stability may be generally produced, or if the basic catalyst remains, a radiation sensitive composition deteriorated in sensitivity may be generally produced, and therefore such purification may also be conducted for the purpose of a reduction in the amount. Such purification can be performed by a known method, as long as the polymer is not modified, and is not particularly limited, and examples thereof include a method of washing the polymer with water, a method of washing the polymer with an acidic aqueous solution, a method of washing the polymer with a basic aqueous solution, a method of treating the polymer with an ion exchange resin, and a method of treating the polymer by silica gel chromatography. These purification methods are more preferably performed in combinations of two or more. The acidic aqueous solution, the basic aqueous solution, the ion exchange resin and the silica gel chromatography can be appropriately selected optimally depending on the metal to be removed, the amount(s) and the kind(s) of the acidic compound and/or the basic compound, the kind of a dissolution inhibitor for purification, and the like. Examples of the acidic aqueous solution include aqueous hydrochloric acid, nitric acid and acetic acid solutions each having a concentration of 0.01 to 10 mol/L, examples of the basic aqueous solution include an aqueous ammonia solution having a concentration of 0.01 to 10 mol/L, and examples of the ion exchange resin include a cation exchange resin such as Amberlyst 15J-HG Dry produced by Organo Corporation. Drying may also be performed after such purification. Drying can be performed by a known method and is not particularly limited, and examples thereof include a vacuum or hot air drying method under a condition where the polymer is not modified.

The polymer compound of the present embodiment is preferably low in sublimability at an ordinary pressure and at 100° C. or lower, preferably 120° C. or lower, more preferably 130° C. or lower, further preferably 140° C. or lower, particularly preferably 150° C. or lower. The phrase “low in sublimability” preferably means that the weight loss in holding at a predetermined temperature for 10 minutes in thermogravimetric analysis is 10%, preferably 5%, more preferably 3%, further preferably 1%, particularly preferably 0.1% or less. Low sublimability enables to prevent an exposure apparatus from being contaminated due to outgas in exposure, and moreover, enables to provide a good pattern having low line edge roughness (hereinafter, sometimes simply referred to as “LER”).

The polymer compound of the present embodiment preferably satisfies F<3.0 (F represents the total number of atoms/(the total number of carbon atoms−the total number of oxygen atoms)), more preferably F<2.5. The condition can be satisfied to result in an enhancement in dry etching resistance.

A non-acid-dissociable functional group may also be introduced to at least one phenolic hydroxy group and/or carboxyl group of the polymer compound as long as the effect of the present invention is not impaired. The non-acid-dissociable functional group refers to a characteristic group that is not cleaved in the presence of an acid and that generates no alkali soluble group. Examples include a functional group selected from the group consisting of an alkyl group having 1 to 20 carbon atoms, a cycloalkyl group having 3 to 20 carbon atoms, an aryl group having 6 to 20 carbon atoms, an alkoxyl group having 1 to 20 carbon atoms, a cyano group, a nitro group, a hydroxy group, a heterocyclic group, a halogen atom, a carboxyl group, an alkylsilyl group having 1 to 20 carbon atoms, and derivatives thereof, which are not decomposed by the action of an acid.

The number average molecular weight (Mn) in terms of polystyrene, of the polymer compound of the present embodiment, is preferably 1000 to 50000, further preferably 1500 to 10000, particularly preferably 2500 to 7500. When the number average molecular weight of the polymer compound of the present embodiment is in the above range, not only film formation property necessary for a resist is held, but also pattern collapse can be suppressed to result in an enhancement in resolution.

The dispersity of the polymer compound of the present embodiment (weight average molecular weight/number average molecular weight (hereinafter, sometimes simply referred to as “Mw/Mn”) is preferably Mw/Mn<1.7, further preferably Mw/Mn<1.5, more preferably Mw/Mn<1.3 in terms of sensitivity, more preferably Mw/Mn<1.2, particularly preferably Mw/Mn<1.1 in terms of low roughness.

The polymer compound of the present embodiment is particularly preferably a compound represented by the following general formula (5) obtained by reacting the compound represented by the general formula (3) with any compound of the group represented by the general formula (4) and thereafter reacting one of the compound represented by the general formula (3) therewith.

The polymer compound of the present embodiment has a large number of such tube-shaped structures, therefore is not gelled, is excellent in solvent solubility and has a large number of holes, and thus is very high in sensitivity.

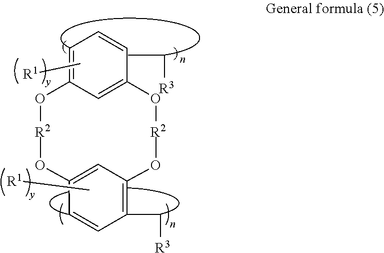

In the general formula (5), R¹, R², R³ and y have the same meaning as defined in the general formula (1), and n represents an integer of 4 to 8.

The polymer compound of the present embodiment is preferably a compound represented by the following general formula (X).

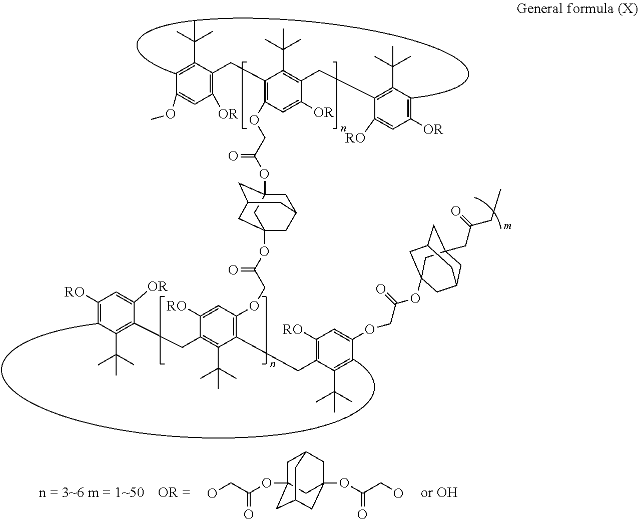

Hereinafter, specific examples of the polymer compound of the present embodiment are shown. The polymer compound of the present embodiment, however, is not limited to the following specific examples.

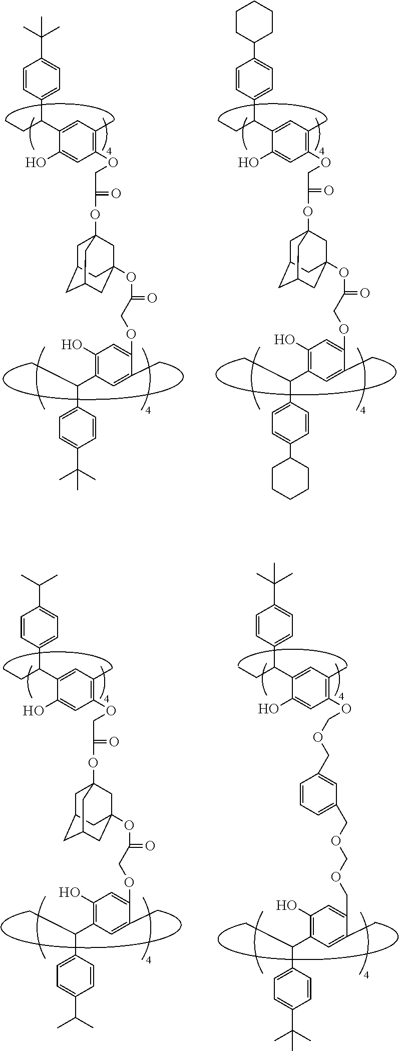

The polymer compound of the present embodiment can be used to result in enhancements in strength of the resulting resist pattern and adhesiveness thereof to the base material, thereby allowing the problem of pattern collapse observed in the case of a low-molecular, to be suppressed. The polymer compound of the present embodiment can have a reduced molecular weight due to elimination of a crosslinking protective group in an exposed portion, thereby reducing roughness of a resist pattern, as in the case of a low-molecular. The polymer compound of the present embodiment is high in heat resistance and has amorphous property to thereby also be excellent in film formation property, has no sublimability and is excellent in development property, etching resistance and the like, and can be suitably used as a resist material, in particular a main component (base material) of a resist material.

Furthermore, the polymer compound of the present embodiment has a tube-shaped structure, therefore is not gelled, is excellent in solvent solubility and furthermore has a large number of holes, and thus is very high in sensitivity. Also in terms of production, the polymer compound can be produced at a high yield by reacting the compound represented by the general formula (3) with any compound of the group represented by the general formula (4) that is easily available as an industrial product, and therefore is also extremely excellent in practicality.

### (Radiation Sensitive Composition)

A radiation sensitive composition of the present embodiment has the polymer compound of the present embodiment. The radiation sensitive composition of the present embodiment may also include a solvent, if necessary. The radiation sensitive composition of the present embodiment can preferably include an acid generator (C) that directly or indirectly generates an acid by irradiation with any radiation selected from the group consisting of a visible light ray, an ultraviolet ray, an excimer laser, an electron beam, an extreme ultraviolet ray (EUV), an X-ray and an ion beam, an acid diffusion inhibitor (E) and a solvent.

An amorphous film can be formed from the radiation sensitive composition of the present embodiment by a method such as spin coating. The radiation sensitive composition of the present embodiment can also separately form any of a positive resist pattern and a negative resist pattern depending on a developer to be used. For example, when an alkali developer is used, a positive pattern is obtained, and when an organic developer is used, a negative pattern is obtained.

In the case of formation of the positive resist pattern, the dissolution rate at 23° C. of an amorphous film formed by spin coating with the radiation sensitive composition of the present embodiment, in the developer, is preferably 5 Å/sec or less, more preferably 0.05 to 5 Å/sec, further preferably 0.0005 to 5 Å/sec. When the dissolution rate is 5 Å/sec or less, a resist insoluble in the developer can be obtained. When the radiation sensitive composition of the present embodiment has a dissolution rate of 0.0005 Å/sec or more, an enhancement in resolution may also be achieved. The reason for such an enhancement is presumed as follows: the change in solubility before and after exposure of the polymer compound of the present embodiment allows the contrast at an interface between an exposed portion dissolved in the developer and an unexposed portion not dissolved in the developer to be increased. When the radiation sensitive composition of the present embodiment is used, the reduction effect of line edge roughness and the defect reduction effect are exerted.

In the case of formation of the negative resist pattern, the dissolution rate at 23° C. of an amorphous film formed by spin coating with the radiation sensitive composition of the present embodiment, in the developer, is preferably 10 Å/sec or more. When the dissolution rate is 10 Å/sec or more, the radiation sensitive composition is easily dissolved in the developer and is more suitable for a resist. When the radiation sensitive composition has a dissolution rate of 10 Å/sec or more, an enhancement in resolution may also be achieved. The reason for such an enhancement is presumed as follows: the microscopic surface site of the polymer compound of the present embodiment is dissolved to result in a reduction in the line edge roughness. When the radiation sensitive composition of the present embodiment is used, the defect reduction effect is exerted.

The dissolution rate can be calculated based on the measurement value obtained by immersing the amorphous film in the developer at 23° C. for a predetermined time and measuring the variation in film thickness before and after such immersion by a known method such as visual contact, an ellipsometer or a QCM method.

In the case of formation of the positive resist pattern, the dissolution rate at 23° C. of a portion of the amorphous film formed by spin coating with the radiation sensitive composition of the present embodiment, exposed to a radiation such as a KrF excimer laser, an extreme ultraviolet ray, an electron beam or an X-ray, in the developer, is preferably 10 Å/sec or more. When the dissolution rate is 10 Å/sec or more, the radiation sensitive composition is easily dissolved in the developer and is more suitable for a resist. When the radiation sensitive composition has a dissolution rate of 10 Å/sec or more, an enhancement in resolution may also be achieved. The reason for such an enhancement is presumed as follows: the microscopic surface site of the polymer compound of the present embodiment is dissolved to result in a reduction in the line edge roughness. When the radiation sensitive composition of the present embodiment is used, the defect reduction effect is exerted.

In the case of formation of the negative resist pattern, the dissolution rate at 23° C. of a portion of the amorphous film formed by spin coating with the radiation sensitive composition of the present embodiment, exposed to a radiation such as a KrF excimer laser, an extreme ultraviolet ray, an electron beam or an X-ray, in the developer, is preferably 5 Å/sec or less, more preferably 0.05 to 5 Å/sec, further preferably 0.0005 to 5 Å/sec.

When the dissolution rate is 5 Å/sec or less, a resist insoluble in the developer can be obtained. When the radiation sensitive composition has a dissolution rate of 0.0005 Å/sec or more, an enhancement in resolution may also be achieved. The reason for such an enhancement is presumed as follows: the change in solubility before and after exposure of the polymer compound of the present embodiment allows the contrast at an interface between an exposed portion dissolved in the developer and an unexposed portion not dissolved in the developer to be increased. When the radiation sensitive composition of the present embodiment is used, the reduction effect of line edge roughness and the defect reduction effect are exerted.

The radiation sensitive composition of the present embodiment can be formed as a composition having, for example, a solid content of 1 to 80% by mass and a solvent content of 20 to 99% by mass, preferably a solid content of 1 to 50% by mass and a solvent content of 50 to 99% by mass, further preferably a solid content of 2 to 40% by mass and a solvent content of 60 to 98% by mass, particularly preferably a solid content of 2 to 10% by mass and a solvent content of 90 to 98% by mass.

The content of the polymer compound of the present embodiment in the radiation sensitive composition is 10 to 90% by mass, preferably 30 to 90% by mass, more preferably 50 to 80% by mass, particularly preferably 70 to 75% by mass based on the total solid content. When the content of the polymer compound of the present embodiment in the radiation sensitive composition is the above compounding proportion, a higher resolution is achieved and a smaller line edge roughness is achieved.

### (Acid Generator (C))

The radiation sensitive composition of the present embodiment preferably contain at least one acid generator (C) that directly or indirectly generates an acid by irradiation with any radiation selected from a visible light ray, an ultraviolet ray, an excimer laser, an electron beam, an extreme ultraviolet ray (EUV), an X-ray and an ion beam.

In such a case, the content of the acid generator (C) in the radiation sensitive composition of the present embodiment is preferably 0.001 to 50% by mass, more preferably 10 to 37.5% by mass, particularly preferably 10 to 30% by mass based on the total solid content. The acid generator (C) is used in the above content range to thereby provide a pattern profile higher in sensitivity and lower in edge roughness.

In the resist composition of the present embodiment, the method of generating an acid is not limited as long as an acid is generated in the system. An excimer laser can be used instead of an ultraviolet ray such as a g-line or an i-line to thereby allow for finer processing, and an electron beam, an extreme ultraviolet ray, an X-ray or an ion beam can be used as a high energy line to thereby allow for much finer processing.

The acid generator (C) is preferably at least one selected from the group consisting of compounds represented by the following formulae (7-1) to (7-8).

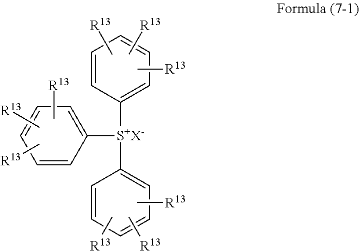

In the formula (7-1), each R¹³ may be the same or different, and independently represents a hydrogen atom, a straight, branched or cyclic alkyl group, a straight, branched or cyclic alkoxy group, a hydroxyl group, or a halogen atom; and X⁻ represents a sulfonic acid ion having an alkyl group, an aryl group, a halogen-substituted alkyl group or a halogen-substituted aryl group, or a halide ion.

The compound represented by the formula (7-1) is preferably at least one selected from the group consisting of triphenylsulfonium trifluoromethanesulfonate, triphenylsulfonium nonafluoro-n-butanesulfonate, diphenyltolylsulfonium nonafluoro-n-butanesulfonate, triphenylsulfonium perfluoro-n-octanesulfonate, diphenyl-4-methylphenylsulfonium trifluoromethanesulfonate, di-2,4,6-trimethylphenylsulfonium trifluoromethanesulfonate, diphenyl-4-t-butoxyphenylsulfonium trifluoromethanesulfonate, diphenyl-4-t-butoxyphenylsulfonium nonafluoro-n-butanesulfonate, diphenyl-4-hydroxyphenylsulfonium trifluoromethanesulfonate, bis(4-fluorophenyl)-4-hydroxyphenylsulfonium trifluoromethanesulfonate, diphenyl-4-hydroxyphenylsulfonium nonafluoro-n-butanesulfonate, bis(4-hydroxyphenyl)-phenylsulfonium trifluoromethanesulfonate, tri(4-methoxyphenyl)sulfonium trifluoromethanesulfonate, tri(4-fluorophenyl)sulfonium trifluoromethanesulfonate, triphenylsulfonium p-toluenesulfonate, triphenylsulfonium benzenesulfonate, diphenyl-2,4,6-trimethylphenyl-p-toluenesulfonate, diphenyl-2,4,6-trimethylphenylsulfonium-2-trifluoromethylbenzenesulfonate, diphenyl-2,4,6-trimethylphenylsulfonium-4-trifluoromethylbenzenesulfonate, diphenyl-2,4,6-trimethylphenylsulfonium-2,4-difluorobenzenesulfonate, diphenyl-2,4,6-trimethylphenylsulfonium hexafluorobenzenesulfonate, diphenylnaphthylsulfonium trifluoromethanesulfonate, diphenyl-4-hydroxyphenylsulfonium-p-toluenesulfonate, triphenylsulfonium 10-camphorsulfonate, diphenyl-4-hydroxyphenylsulfonium 10-camphorsulfonate and cyclo(1,3-perfluoropropanedisulfone)imidate.

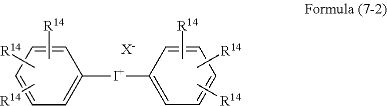

In the formula (7-2), each R¹⁴ may be the same or different, and independently represents a hydrogen atom, a straight, branched or cyclic alkyl group, a straight, branched or cyclic alkoxy group, a hydroxyl group, or a halogen atom. X⁻ has the same meaning as defined in the formula (7-1).

The compound represented by the formula (7-2) is preferably at least one selected from the group consisting of bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium p-toluenesulfonate, bis(4-t-butylphenyl)iodonium benzenesulfonate, bis(4-t-butylphenyl)iodonium-2-trifluoromethylbenzenesulfonate, bis(4-t-butylphenyl)iodonium-4-trifluoromethylbenzenesulfonate, bis(4-t-butylphenyl)iodonium-2,4-difluorobenzenesulfonate, bis(4-t-butylphenyl)iodonium hexafluorobenzenesulfonate, bis(4-t-butylphenyl)iodonium 10-camphorsulfonate, diphenyliodonium trifluoromethanesulfonate, diphenyliodonium nonafluoro-n-butanesulfonate, diphenyliodonium perfluoro-n-octanesulfonate, diphenyliodonium p-toluenesulfonate, diphenyliodonium benzenesulfonate, diphenyliodonium 10-camphorsulfonate, diphenyliodonium-2-trifluoromethylbenzenesulfonate, diphenyliodonium-4-trifluoromethylbenzenesulfonate, diphenyliodonium-2,4-difluorobenzenesulfonate, diphenyliodonium hexafluorobenzenesulfonate, di(4-trifluoromethylphenyl)iodonium trifluoromethanesulfonate, di(4-trifluoromethylphenyl)iodonium nonafluoro-n-butanesulfonate, di(4-trifluoromethylphenyl)iodonium perfluoro-n-octanesulfonate, di(4-trifluoromethylphenyl)iodonium p-toluenesulfonate, di(4-trifluoromethylphenyl)iodonium benzenesulfonate and di(4-trifluoromethylphenyl)iodonium 10-camphorsulfonate.

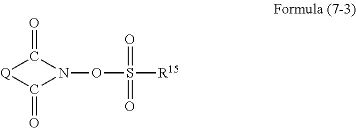

In the formula (7-3), Q represents an alkylene group, an arylene group or an alkoxylene group, and R¹⁵ represents an alkyl group, an aryl group, a halogen-substituted alkyl group or a halogen-substituted aryl group.

The compound represented by the formula (7-3) is preferably at least one selected from the group consisting of N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hept-5-ene-2,3-dicarboxyimide, N-(trifluoromethylsulfonyloxy)naphthylimide, N-(10-camphorsulfonyloxy)succinimide, N-(10-camphorsulfonyloxy)phthalimide, N-(10-camphorsulfonyloxy)diphenylmaleimide, N-(10-camphorsulfonyloxy)bicyclo[2.2.1]hept-5-ene-2,3-dicarboxyimide, N-(10-camphorsulfonyloxy)naphthylimide, N-(n-octanesulfonyloxy)bicyclo[2.2.1]hept-5-ene-2,3-dicarboxyimide, N-(n-octanesulfonyloxy)naphthylimide, N-(p-toluenesulfonyloxy)bicyclo[2.2.1]hept-5-ene-2,3-dicarboxyimide, N-(p-toluenesulfonyloxy)naphthylimide, N-(2-trifluoromethylbenzenesulfonyloxy)bicyclo[2.2.1]hept-5-ene-2,3-dicarboxyimide, N-(2-trifluoromethylbenzenesulfonyloxy)naphthylimide, N-(4-trifluoromethylbenzenesulfonyloxy)bicyclo[2.2.1]hept-5-ene-2,3-dicarboxyimide, N-(4-trifluoromethylbenzenesulfonyloxy)naphthylimide, N-(perfluorobenzenesulfonyloxy)bicyclo[2.2.1]hept-5-ene-2,3-dicarboxyimide, N-(perfluorobenzenesulfonyloxy)naphthylimide, N-(1-naphthalenesulfonyloxy)bicyclo[2.2.1]hept-5-ene-2,3-dicarboxyimide, N-(1-naphthalenesulfonyloxy)naphthylimide, N-(nonafluoro-n-butanesulfonyloxy)bicyclo[2.2.1]hept-5-ene-2,3-dicarboxyimide, N-(nonafluoro-n-butanesulfonyloxy)naphthylimide, N-(perfluoro-n-octanesulfonyloxy)bicyclo[2.2.1]hept-5-ene-2,3-dicarboxyimide and N-(perfluoro-n-octanesulfonyloxy)naphthylimide.

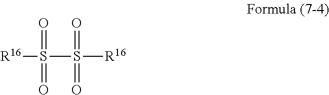

In the formula (7-4), each R¹⁶ may be the same or different, and independently represents an optionally substituted straight, branched or cyclic alkyl group, an optionally substituted aryl group, an optionally substituted heteroaryl group, or an optionally substituted aralkyl group.

The compound represented by the formula (7-4) is preferably at least one selected from the group consisting of diphenyldisulfone, di(4-methylphenyl)disulfone, dinaphthyldisulfone, di(4-tert-butylphenyl)disulfone, di(4-hydroxyphenyl)disulfone, di(3-hydroxynaphthyl)disulfone, di(4-fluorophenyl)disulfone, di(2-fluorophenyl)disulfone and di(4-trifluoromethylphenyl)disulfone.

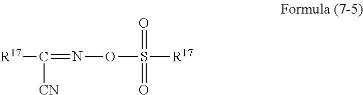

In the formula (7-5), each R¹⁷ may be the same or different, and independently represents an optionally substituted straight, branched or cyclic alkyl group, an optionally substituted aryl group, an optionally substituted heteroaryl group, or an optionally substituted aralkyl group.

The compound represented by the formula (7-5) is preferably at least one selected from the group consisting of α-(methylsulfonyloxyimino)-phenylacetonitrile, α-(methylsulfonyloxyimino)-4-methoxyphenylacetonitrile, α-(trifluoromethylsulfonyloxyimino)-phenylacetonitrile, α-(trifluoromethylsulfonyloxyimino)-4-methoxyphenylacetonitrile, α-(ethylsulfonyloxyimino)-4-methoxyphenylacetonitrile, α-(propylsulfonyloxyimino)-4-methylphenylacetonitrile and α-(methylsulfonyloxyimino)-4-bromophenylacetonitrile.

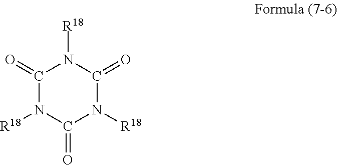

In the formula (7-6), each R¹⁸ may be the same or different, and independently represents a halogenated alkyl group having one or more chlorine atoms and one or more bromine atoms. The number of carbon atoms in the halogenated alkyl group is preferably 1 to 5.

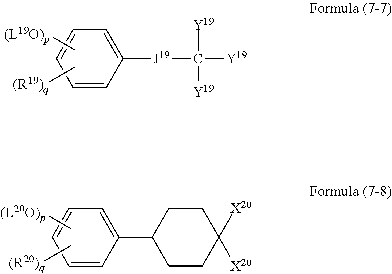

In the formulae (7-7) and (7-8), each of R¹⁹ and R²⁰ independently represents an alkyl group having 1 to 3 carbon atoms, such as a methyl group, an ethyl group, a n-propyl group or an isopropyl group, a cycloalkyl group such as a cyclopentyl group or a cyclohexyl group, an alkoxyl group having 1 to 3 carbon atoms, such as a methoxy group, an ethoxy group or a propoxy group, or an aryl group such as a phenyl group, a toluyl group or a naphthyl group, preferably represents an aryl group having 6 to 10 carbon atoms, and each of L¹⁹ and L²⁰ independently represents an organic group having a 1,2-naphthoquinonediazide group. Specific preferable examples of the organic group having a 1,2-naphthoquinonediazide group can include 1,2-quinonediazide sulfonyl groups such as a 1,2-naphthoquinonediazide-4-sulfonyl group, a 1,2-naphthoquinonediazide-5-sulfonyl group and a 1,2-naphthoquinonediazide-6-sulfonyl group. In particular, a 1,2-naphthoquinonediazide-4-sulfonyl group and a 1,2-naphthoquinonediazide-5-sulfonyl group are preferable. Each p independently represents an integer of 1 to 3, each q independently represents an integer of 0 to 4, and 1≦p+q≦5 is satisfied. Jn represents a single bond, a polymethylene group having 1 to 4 carbon atoms, a cycloalkylene group, a phenylene group, a group represented by the following formula (7-7-1), a carbonyl group, an ester group, an amide group or an ether group, Y¹⁹ represents a hydrogen atom, an alkyl group or an aryl group, and each X²⁰ independently represents a group represented by the following formula (7-8-1).

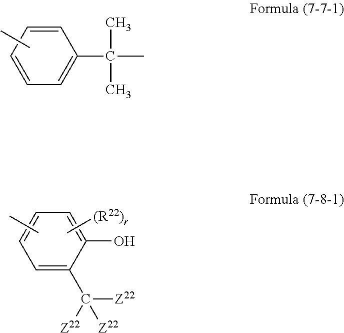

In the formula (7-8-1), each Z²² independently represents an alkyl group, a cycloalkyl group or an aryl group, R²² represents an alkyl group, a cycloalkyl group or an alkoxyl group, and r represents an integer of 0 to 3.

Other examples of the acid generator include bissulfonyldiazomethanes such as bis(p-toluenesulfonyl) diazomethane, bis(2,4-dimethylphenylsulfonyl)diazomethane, bis(tert-butylsulfonyl)diazomethane, bis(n-butylsulfonyl)diazomethane, bis(isobutylsulfonyl)diazomethane, bis(isopropylsulfonyl)diazomethane, bis(n-propylsulfonyl)diazomethane, bis(cyclohexylsulfonyl)diazomethane, bis(isopropylsulfonyl)diazomethane, 1,3-bis(cyclohexylsulfonylazomethylsulfonyl)propane, 1,4-bis(phenylsulfonylazomethylsulfonyl)butane, 1,6-bis(phenylsulfonylazomethylsulfonyl)hexane and 1,10-bis(cyclohexylsulfonylazomethylsulfonyl)decane, and halogen-containing triazine derivatives such as 2-(4-methoxyphenyl)-4,6-(bistrichloromethyl)-1,3,5-triazine, 2-(4-methoxynaphthyl)-4,6-(bistrichloromethyl)-1,3,5-triazine, tris(2,3-dibromopropyl)-1,3,5-triazine and tris(2,3-dibromopropyl)isocyanurate.

Among the above acid generators, the acid generator (C) for use in the radiation sensitive composition of the present embodiment is preferably an acid generator having an aromatic ring, more preferably an acid generator represented by formula (7-1) or (7-2). An acid generator in which X⁻ in the formula (7-1) or (7-2) represents a sulfonic acid ion having an aryl group or a halogen-substituted aryl group is further preferable, an acid generator having a sulfonic acid ion having an aryl group is particularly preferable, and diphenyltrimethylphenylsulfonium p-toluenesulfonate, triphenylsulfonium p-toluenesulfonate, triphenylsulfonium trifluoromethanesulfonate or triphenylsulfonium nonafluoromethanesulfonate is particularly preferable. Such an acid generator can be used to thereby result in a reduction in line edge roughness.

The acid generator (C) can be used singly or in combinations of two or more.

### (Acid Diffusion Inhibitor (E))

An acid diffusion inhibitor (E), which has the action of controlling diffusion of the acid generated from the acid generator by irradiation with a radiation in a resist film, thereby inhibiting an unpreferred chemical reaction in an unexposed portion, may also be compounded in the radiation sensitive composition of the present embodiment. Such an acid diffusion inhibitor (E) is used to thereby result in an enhancement in storage stability of the radiation sensitive composition and also an enhancement in resolution, and enable to suppress the change in line width of a resist pattern due to the variations in post-exposure delay before irradiation with an electron beam and in that after irradiation with an electron beam, providing an extremely excellent process stability. Such an acid diffusion inhibitor (E) includes electron beam radiation decomposable basic compounds such as a nitrogen atom-containing basic compound, a basic sulfonium compound and a basic iodonium compound. The acid diffusion inhibitor can be used singly or in combinations of two or more.

Examples of the acid diffusion inhibitor include a nitrogen-containing organic compound and a basic compound that is decomposed by exposure. Examples of the nitrogen-containing organic compound can include a compound represented by the following general formula (10) (hereinafter, referred to as “nitrogen-containing compound (I)”), a diamino compound having two nitrogen atoms in the same molecule (hereinafter, referred to as “nitrogen-containing compound (II)”), a polyamino compound or a polymer having three or more nitrogen atoms (hereinafter, referred to as “nitrogen-containing compound (III)”), an amide group-containing compound, a urea compound, and a nitrogen-containing heterocyclic compound. Herein, the acid diffusion inhibitor may be used singly, or may be used in combinations of two or more.

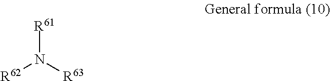

In the general formula (10), R⁶¹, R⁶² and R⁶³ mutually independently represent a hydrogen atom, a straight, branched or cyclic alkyl group, an aryl group, or an aralkyl group. The alkyl group, the aryl group or the aralkyl group may be unsubstituted, or may be substituted with other functional group such as a hydroxyl group. Examples of the straight, branched or cyclic alkyl group include those having 1 to 15 carbon atoms, preferably 1 to 10 carbon atoms, specifically, a methyl group, an ethyl group, a n-propyl group, an isopropyl group, a n-butyl group, an isobutyl group, a sec-butyl group, a t-butyl group, a n-pentyl group, a neopentyl group, a n-hexyl group, a thexyl group, a n-heptyl group, a n-octyl group, a n-ethylhexyl group, a n-nonyl group and a n-decyl group. Examples of the aryl group include those having 6 to 12 carbon atoms, specifically, a phenyl group, a tolyl group, a xylyl group, a cumenyl group and a 1-naphthyl group. Furthermore, examples of the aralkyl group include those having 7 to 19 carbon atoms, preferably 7 to 13 carbon atoms, specifically, a benzyl group, an α-methylbenzyl group, a phenethyl group and a naphthylmethyl group.

Specific examples of the nitrogen-containing compound (I) can include mono(cyclo)alkylamines such as n-hexylamine, n-heptylamine, n-octylamine, n-nonylamine, n-decylamine, n-dodecylamine and cyclohexylamine; di(cyclo)alkylamines such as di-n-butylamine, di-n-pentylamine, di-n-hexylamine, di-n-heptylamine, di-n-octylamine, di-n-nonylamine, di-n-decylamine, methyl-n-dodecylamine, di-n-dodecylmethyl, cyclohexylmethylamine and dicyclohexylamine; tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, dimethyl-n-dodecylamine, di-n-dodecylmethylamine, dicyclohexylmethylamine and tricyclohexylamine; alkanolamines such as monoethanolamine, diethanolamine and triethanolamine; and aromatic amines such as aniline, N-methylaniline, N,N-dimethylaniline, 2-methylaniline, 3-methylaniline, 4-methylaniline, 4-nitroaniline, diphenylamine, triphenylamine and 1-naphthylamine.

Specific examples of the nitrogen-containing compound (II) can include ethylenediamine, N,N,N′,N′-tetramethylethylenediamine, N,N,N′,N′-tetrakis(2-hydroxypropyl)ethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene and 1,3-bis[1-(4-aminophenyl)-1-methylethyl]benzene.

Specific examples of the nitrogen-containing compound (III) can include polyethyleneimine, polyallylamine, and a polymer of N-(2-dimethylaminoethyl)acrylamide.

Specific examples of the amide group-containing compound can include formamide, N-methylformamide, N,N-dimethylformamide, acetamide, N-methyl acetamide, N,N-dimethyl acetamide, propionamide, benzamide, pyrrolidone and N-methylpyrrolidone.

Specific examples of the urea compound can include urea, methylurea, 1,1-dimethylurea, 1,3-dimethylurea, 1,1,3,3-tetramethylurea, 1,3-diphenylurea and tri-n-butylthiourea.

Specific examples of the nitrogen-containing heterocyclic compound can include imidazoles such as imidazole, benzimidazole, 4-methylimidazole, 4-methyl-2-phenylimidazole and 2-phenylbenzimidazole; pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotine acid, nicotinamide, quinoline, 8-oxyquinoline and acridine; and pyrazine, pyrazole, pyridazine, quinoxaline, purine, pyrrolidine, piperidine, morpholine, 4-methylmorpholine, piperazine, 1,4-dimethylpiperazine and 1,4-diazabicyclo[2.2.2]octane.

Examples of the basic compound that is decomposed by exposure can include a sulfonium compound represented by the following general formula (11-1) and an iodonium compound represented by the following general formula (11-2).

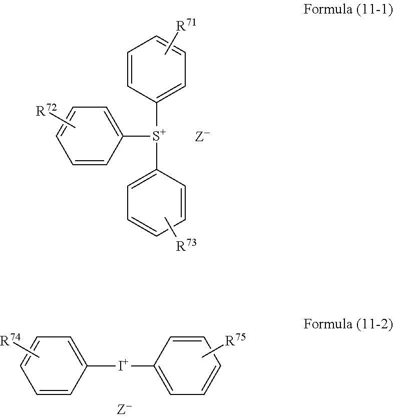

In the general formulae (11-1) and (11-2), R⁷¹, R⁷², R⁷³, R⁷⁴ and R⁷⁵ mutually independently represent a hydrogen atom, an alkyl group having 1 to 6 carbon atoms, an alkoxyl group having 1 to 6 carbon atoms, a hydroxyl group or a halogen atom. Z⁻ represents HO⁻, R—COO⁻ (provided that R represents an alkyl group having 1 to 6 carbon atoms, an aryl group having 1 to 6 carbon atoms or an alkaryl group having 1 to 6 carbon atoms), or an anion represented by the following general formula (11-3).

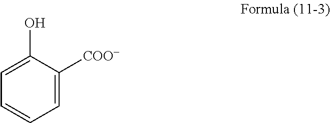

Specific examples of the basic compound that is decomposed by exposure include triphenylsulfonium hydroxide, triphenylsulfonium acetate, triphenylsulfonium salicylate, diphenyl-4-hydroxyphenylsulfonium hydroxide, diphenyl-4-hydroxyphenylsulfonium acetate, diphenyl-4-hydroxyphenylsulfonium salicylate, bis(4-t-butylphenyl)iodonium hydroxide, bis(4-t-butylphenyl)iodonium acetate, bis(4-t-butylphenyl)iodonium hydroxide, bis(4-t-butylphenyl)iodonium acetate, bis(4-t-butylphenyl)iodonium salicylate, 4-t-butylphenyl-4-hydroxyphenyliodonium hydroxide, 4-t-butylphenyl-4-hydroxyphenyliodonium acetate and 4-t-butylphenyl-4-hydroxyphenyliodonium salicylate.

The content of the acid diffusion inhibitor (E) is preferably 0.001 to 50% by mass, more preferably 0.001 to 10% by mass, further preferably 0.001 to 5% by mass, particularly preferably 0.001 to 3% by mass based on the total solid mass of the radiation sensitive composition. When the content of the acid diffusion inhibitor (E) is in the above range, a reduction in resolution, and deteriorations in a pattern shape, dimensional fidelity, and the like can be prevented. Furthermore, even when the post-exposure delay from the completion of irradiation with an electron beam until the initiation of heating after irradiation with a radiation is increased, the shape of a pattern upper layer portion is not deteriorated. When the content of the acid diffusion inhibitor (E) is 10% by mass or less, deteriorations in sensitivity, development property of an unexposed portion, and the like can be prevented. Such an acid diffusion inhibitor is used to thereby result in an enhancement in storage stability of a radiation sensitive composition and also an enhancement in resolution, and enable to suppress the change in line width of a resist pattern due to the variations in post-exposure delay before irradiation with a radiation and in that after irradiation with a radiation, providing an extremely excellent process stability.

### (Other Component(s) (F))

Various additives such as a dissolution promoter, a dissolution inhibitor, a sensitizer, a surfactant and an organic carboxylic acid or an oxo acid of phosphorus or a derivative thereof can be if necessary added as other component(s) (F) to the radiation sensitive composition of the present embodiment singly or in combinations of two or more as long as the effect of the present invention is not impaired.

### (1) Dissolution Promoter

A low-molecular weight dissolution promoter is a component which, when the solubility of the resist base material in the developer such as an alkali is too low, has the action of increasing the solubility to properly increase the dissolution rate of the cyclic compound in development, and can be used as long as the effect of the present invention is not impaired. Examples of the dissolution promoter can include a low-molecular weight phenolic compound, and examples can include bisphenols and tris(hydroxyphenyl)methane. Such dissolution promoters can be used singly or as a mixture of two or more. The amount of the dissolution promoter to be compounded is appropriately regulated depending on the kind of the resist base material to be used, and the amount thereof per 100 parts by mass of the resist base material (polymer, hereinafter, referred to as “the polymer compound of the present embodiment”) is preferably 0 to 100 parts by mass, preferably 0 to 30 parts by mass, more preferably 0 to 10 parts by mass, further preferably 0 to 2 parts by mass.

### (2) Dissolution Inhibitor

The dissolution inhibitor is a component which, when the solubility of the resist base material in the developer such as an alkali is too high, has the action of controlling the solubility to properly reduce the dissolution rate in development. Such a dissolution inhibitor is preferably one that is not chemically changed in a step of firing of a resist coating, a step of irradiating a resist coating with a radiation, a step of developing a resist coating, and the like. Examples of the dissolution inhibitor can include aromatic hydrocarbons such as naphthalene, phenanthrene, anthracene and acenaphthene; ketones such as acetophenone, benzophenone and phenyl naphthyl ketone; and sulfones such as methylphenylsulfone, diphenylsulfone and dinaphthylsulfone. These dissolution inhibitors can be used singly or in combinations of two or more.

The amount of the dissolution inhibitor to be compounded is appropriately regulated depending on the kind of the polymer compound of the present embodiment to be used, and the amount thereof per 100 parts by mass of the polymer compound of the present embodiment is preferably 0 to 100 parts by mass, preferably 0 to 30 parts by mass, more preferably 0 to 10 parts by mass, further preferably 0 to 2 parts by mass.

### (3) Sensitizer

The sensitizer is a component which has the action of absorbing the energy of a radiation for irradiation, to transfer the energy to the acid generator (C), thereby increasing the amount of the acid to be generated, and which enhances the apparent sensitivity of the resist. Examples of such a sensitizer can include benzophenones, bisacetyls, pyrenes, phenothiazines and fluorenes, but not particularly limited.

These sensitizers can be used singly or in combinations of two or more. The amount of the sensitizer to be compounded is appropriately regulated depending on the kind of the polymer compound of the present embodiment to be used, and the amount thereof per 100 parts by mass of the polymer compound of the present embodiment is preferably 0 to 100 parts by mass, preferably 0 to 30 parts by mass, more preferably 0 to 10 parts by mass, further preferably 0 to 2 parts by mass.

### (4) Surfactant

The surfactant is a component which has the action of improving coatability of the radiation sensitive composition of the present invention, suppressing striation thereof, and improving development property and the like of the resist. Such a surfactant may be any anionic, cationic, nonionic or amphoteric surfactant. A preferable surfactant is a nonionic surfactant. The nonionic surfactant has a good affinity with the solvent for use in the radiation sensitive composition, and is more effective. Examples of the nonionic surfactant include polyoxyethylene higher alkyl ethers, polyoxyethylene higher alkyl phenyl ethers and polyethylene glycol higher fatty acid diesters, but not particularly limited. Examples of a commercial product can include products of the following tradenames: Eftop (produced by Jemco Inc.), Megafac (produced by DIC Corporation), Fluorad (produced by Sumitomo 3M Limited), AsahiGuard and Surflon (all produced by Asahi Glass Co., Ltd.), Pepol (produced by Toho Chemical Industry Co., Ltd.), KP (produced by Shin-Etsu Chemical Co., Ltd.), and Polyflow (produced by Kyoeisha Chemical Co., Ltd.).

The amount of the surfactant to be compounded is appropriately regulated depending on the kind of the polymer compound of the present embodiment to be used, and the amount thereof per 100 parts by mass of the polymer compound of the present embodiment is preferably 0 to 100 parts by mass, preferably 0 to 30 parts by mass, more preferably 0 to 10 parts by mass, further preferably 0 to 2 parts by mass.

### (5) Organic Carboxylic Acid, or Oxo Acid of Phosphorus or Derivative Thereof

The radiation sensitive composition of the present embodiment can further contain, as an optional component, an organic carboxylic acid, or oxo acid of phosphorus or a derivative thereof for the purpose of preventing sensitivity deterioration or improving a resist pattern shape, post-exposure delay stability and the like. Herein, such a component can be used in combination with the acid diffusion inhibitor, or may be used singly. The organic carboxylic acid is suitably, for example, malonic acid, citric acid, malic acid, succinic acid, benzoic acid, salicylic acid or the like. Examples of the oxo acid of phosphorus or derivative thereof include phosphoric acid or derivatives thereof such as esters, for example phosphoric acid, phosphoric acid di-n-butyl ester and phosphoric acid diphenyl ester, phosphonic acid or derivatives thereof such as esters, for example phosphonic acid, phosphonic acid dimethyl ester, phosphonic acid di-n-butyl ester, phenylphosphonic acid, phosphonic acid diphenyl ester and phosphonic acid dibenzyl ester, and phosphinic acid and derivatives thereof such as esters, for example phosphinic acid and phenylphosphinic acid, and among them, phosphonic acid is particularly preferable.

The organic carboxylic acid, or oxo acid of phosphorus or derivative thereof can be used singly or in combinations of two or more. The amount of the organic carboxylic acid, or oxo acid of phosphorus or derivative thereof to be compounded is appropriately regulated depending on the kind of the polymer compound of the present embodiment to be used, and the amount thereof per 100 parts by mass of the polymer compound of the present embodiment is preferably 0 to 100 parts by mass, preferably 0 to 30 parts by mass, more preferably 0 to 10 parts by mass, further preferably 0 to 2 parts by mass.

(6) Other Additive(s) Other than Above Dissolution Inhibitor, Sensitizer, Surfactant and Organic Carboxylic Acid, or Oxo Acid of Phosphorus or Derivative Thereof

Furthermore, additive(s) other than the above dissolution inhibitor, sensitizer and surfactant can be if necessary compounded to the radiation sensitive composition of the present invention singly or in combinations of two or more, as long as the object of the present invention is not inhibited. Examples of such additive(s) include a dye, a pigment and an adhesion aid. For example, the dye or the pigment is preferably compounded because of being capable of visualizing a latent image in an exposed portion to alleviate the influence of halation in exposure. The adhesion aid is preferably compounded because of being capable of improving adhesiveness to the substrate. Furthermore, examples of other additive(s) can include an anti-halation agent, a storage stabilizer, a defoamer and a shape improver, specifically, 4-hydroxy-4′-methylchalcone.

Compounding in the radiation sensitive composition of the present embodiment (the polymer compound of the present embodiment/acid generator (C)/acid diffusion inhibitor (E)/other component (F)) is as follows on the solid basis (parts by mass):

preferably 10 to 90/0.001 to 50/0.01 to 50/0 to 50,
more preferably 30 to 90/0.001 to 50/0.01 to 5/0 to 15,
further preferably 50 to 80/10 to 37.5/0.01 to 3/0 to 1,
particularly preferably 70 to 75/10 to 30/0.01 to 3/0.

The elements included in the radiation sensitive composition of the present embodiment can be compounded as described above to thereby further enhance performances such as sensitivity, resolution and alkali development property.

The radiation sensitive composition of the present embodiment is usually prepared by dissolving the respective components in a solvent in use to provide a uniform solution, and thereafter if necessary filtrating the resultant by a filter having, for example, a pore diameter of about 0.2 μm.

### (Solvent)

Examples of the solvent for use in preparation of the radiation sensitive composition of the present embodiment can include ethylene glycol monoalkyl ether acetates such as ethylene glycol monomethyl ether acetate, ethylene glycol monoethyl ether acetate, ethylene glycol mono-n-propyl ether acetate and ethylene glycol mono-n-butyl ether acetate; ethylene glycol monoalkyl ethers such as ethylene glycol monomethyl ether and ethylene glycol monoethyl ether; propylene glycol monoalkyl ether acetates such as propylene glycol monomethyl ether acetate, propylene glycol monoethyl ether acetate, propylene glycol mono-n-propyl ether acetate and propylene glycol mono-n-butyl ether acetate; propylene glycol monoalkyl ethers such as propylene glycol monomethyl ether and propylene glycol monoethyl ether; lactic acid esters such as methyl lactate, ethyl lactate, n-propyl lactate, n-butyl lactate and n-amyl lactate; aliphatic carboxylic acid esters such as methyl acetate, ethyl acetate, n-propyl acetate, n-butyl acetate, n-amyl acetate, n-hexyl acetate, methyl propionate and ethyl propionate; other esters such as methyl 3-methoxypropionate, ethyl 3-methoxypropionate, methyl 3-ethoxypropionate, ethyl 3-ethoxypropionate, methyl 3-methoxy-2-methylpropionate, 3-methoxybutyl acetate, 3-methyl-3-methoxybutyl acetate, butyl 3-methoxy-3-methylpropionate, butyl 3-methoxy-3-methylbutyrate, methyl acetoacetate, methyl pyruvate and ethyl pyruvate; aromatic hydrocarbons such as toluene and xylene; ketones such as 2-heptanone, 3-heptanone, 4-heptanone, cyclopentanone and cyclohexanone; amides such as N,N-dimethylformamide, N-methyl acetamide, N,N-dimethyl acetamide and N-methylpyrrolidone; and lactones such as γ-lactone, but not particularly limited. These solvents can be used singly or in combinations of two or more.

Examples of the solvent for use in the radiation sensitive composition of the present embodiment can suitably include a solvent selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate and ethyl lactate. As the solvent, a solvent can be preferably used which preferably dissolves 1% by mass or more of the polymer compound of the present embodiment at 23° C., more preferably 5% by mass or more, further preferably 10% by mass or more, particularly preferably 20% by mass or more. The solvent is most preferably selected from PGMEA, PGME and CHN, and a solvent is preferably used which exhibits the highest ability to dissolve the polymer compound of the present embodiment. A solvent that satisfies the above conditions can be used to thereby allow for the use in a semiconductor manufacturing process of actual production, and also make storage stability good.

The radiation sensitive composition of the present embodiment can include a resin soluble in an alkali aqueous solution, as long as the object of the present invention is not inhibited. Examples of the resin soluble in an alkali aqueous solution include a novolac resin, polyvinyl phenols, polyacrylic acid, polyvinyl alcohol, a styrene-maleic anhydride resin, and a polymer including acrylic acid, vinyl alcohol or vinyl phenol as a monomer unit, or derivatives thereof. The amount of the resin soluble in an alkali aqueous solution, to be compounded, is appropriately regulated depending on the kind of the cyclic compound to be used, and the amount thereof per 100 parts by mass of the cyclic compound is preferably 0 to 30 parts by mass, more preferably 0 to 10 parts by mass, further preferably 0 to 5 parts by mass, particularly preferably 0 parts by mass.

### (Resist Pattern Forming Method)

A pattern (resist pattern) forming method of the present embodiment can include forming a film (resist film) on a substrate by use of the radiation sensitive composition of the present embodiment [a film formation step], exposing the film (resist film) [an exposure step], and developing the film (resist film) exposed in the exposure step, to form a pattern (resist pattern) [a development step]. The resist pattern obtained by the pattern forming method of the present embodiment can also be formed as an upper layer resist in a multilayer resist process.

Examples of a specific pattern forming method include, but not particularly limited, the following method. First, in order to form a resist pattern, a conventionally known substrate is coated with the radiation sensitive composition of the present embodiment by a coating procedure such as rotary coating, cast coating or roll coating to thereby form a resist film. The conventionally known substrate is not particularly limited, and examples can include a substrate for electronic components and the substrate on which a predetermined wiring pattern is formed. More specific examples include metallic substrates such as a silicon wafer, copper, chromium, iron and aluminum, and a glass substrate. Examples of the material for the wiring pattern include copper, aluminum, nickel and gold. The substrate on which an inorganic and/or organic film is provided may also be if necessary adopted. Examples of the inorganic film include an inorganic anti-reflective film (inorganic BARC). Examples of the organic film include an organic anti-reflective film (organic BARC). The substrate may also be subjected to a surface treatment with hexamethylenedisilazane or the like.

Next, the substrate coated is if necessary heated. The heating condition is varied depending on the compounding composition of the radiation sensitive composition, and the like, and is preferably 20 to 250° C., more preferably 20 to 150° C. The substrate is preferably heated because adhesiveness of the resist to the substrate may be enhanced by such heating. Next, the resist film is exposed to any radiation selected from the group consisting of a visible light ray, an ultraviolet ray, an excimer laser, an electron beam, an extreme ultraviolet ray (EUV), an X-ray and an ion beam so that a desired pattern is achieved. The exposure condition and the like are appropriately selected depending on the compounding composition of the radiation sensitive composition, and the like. In the present invention, such heating is preferably performed after irradiation with a radiation in order to stably form a high accuracy fine pattern in exposure. The heating condition is varied depending on the compounding composition of the radiation sensitive composition, and the like, and is preferably 20 to 250° C., more preferably 20 to 150° C.

Next, the resist film exposed can be developed by an alkali developer to thereby form a predetermined positive resist pattern. As the alkali developer, for example, an alkaline aqueous solution is used in which at least one alkaline compound of mono-, di- or trialkylamines, mono-, di- or trialkanolamines, heterocyclic amines, tetramethylammonium hydroxide (TMAH), choline and the like is dissolved so that the concentration thereof is preferably 1 to 10% by mass, more preferably 1 to 5% by mass. The concentration of the alkaline aqueous solution is preferably 10% by mass or less because the exposed portion can be inhibited from being dissolved in the developer.

Alcohols such as methanol, ethanol and isopropyl alcohol, and the surfactant can also be added to the alkali developer in proper amounts. Among them, isopropyl alcohol is particularly preferably added in a concentration of 10 to 30% by mass. Thus, it is preferably possible to increase wettability of the developer to the resist. Herein, when a developer including such an alkaline aqueous solution is used, washing with water is generally made after development.

On the other hand, the resist film exposed can be developed by an organic developer to thereby form a predetermined positive or negative resist pattern. As the organic developer, a developer that contains at least one solvent selected from a ketone-based solvent, an ester-based solvent, an alcohol-based solvent, an amide-based solvent and an ether-based solvent is preferable because of improving resist performances such as resolution and roughness of the resist pattern.

The vapor pressure of the developer is not particularly limited, and for example, is preferably 5 kPa or less, further preferably 3 kPa or less, particularly preferably 2 kPa or less at 20° C. The vapor pressure of the developer is 5 kPa or less to thereby inhibit the developer from being evaporated on the substrate or in a development cup, thereby enhancing temperature uniformity in the wafer surface to result in an improvement in dimensional uniformity in the wafer surface.

Specific examples of the developer having a vapor pressure of 5 kPa or less include ketone-based solvents such as 1-octanone, 2-octanone, 1-nonanone, 2-nonanone, 4-heptanone, 2-hexanone, diisobutyl ketone, cyclohexanone, methylcyclohexanone, phenylacetone and methyl isobutyl ketone; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropoinate, 3-methoxybutyl acetate, 3-methyl-3-methoxybutyl acetate, butyl formate, propyl formate, ethyl lactate, butyl lactate and propyl lactate; alcohol-based solvents such as n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol and n-decanol; glycol-based solvents such as ethylene glycol, diethylene glycol and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; ether-based solvents such as tetrahydrofuran; amide-based solvents such as N-methyl-2-pyrrolidone, N,N-dimethyl acetamide and N,N-dimethylformamide; aromatic hydrocarbon-based solvents such as toluene and xylene; and aliphatic hydrocarbon-based solvents such as octane and decane.

Specific examples of the developer having a vapor pressure of 2 kPa or less that is a particularly preferable range include ketone-based solvents such as 1-octanone, 2-octanone, 1-nonanone, 2-nonanone, 4-heptanone, 2-hexanone, diisobutyl ketone, cyclohexanone, methylcyclohexanone and phenylacetone; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropoinate, 3-methoxybutyl acetate, 3-methyl-3-methoxybutyl acetate, ethyl lactate, butyl lactate and propyl lactate; alcohol-based solvents such as n-butyl alcohol, sec-butyl alcohol, tert-butyl alcohol, isobutyl alcohol, n-hexyl alcohol, 4-methyl-2-pentanol, n-heptyl alcohol, n-octyl alcohol and n-decanol; glycol-based solvents such as ethylene glycol, diethylene glycol and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; amide-based solvents such as N-methyl-2-pyrrolidone, N,N-dimethyl acetamide and N,N-dimethylformamide; aromatic hydrocarbon-based solvents such as xylene; and aliphatic hydrocarbon-based solvents such as octane and decane.

A surfactant can be if necessary added to the developer in a proper amount. The surfactant is not particularly limited, and for example, ionic or nonionic fluorine-based and/or silicon-based surfactant(s) can be used. Examples of such fluorine-based and/or silicon-based surfactant(s) can include surfactants described in Japanese Patent Laid-Open No. 62-36663, Japanese Patent Laid-Open No. 61-226746, Japanese Patent Laid-Open No. 61-226745, Japanese Patent Laid-Open No. 62-170950, Japanese Patent Laid-Open No. 63-34540, Japanese Patent Laid-Open No. 7-230165, Japanese Patent Laid-Open No. 8-62834, Japanese Patent Laid-Open No. 9-54432, Japanese Patent Laid-Open No. 9-5988, and U.S. Pat. Nos. 5,405,720, 5,360,692, 5,529,881, 5,296,330, 5,436,098, 5,576,143, 5,294,511 and 5,824,451, and a nonionic surfactant is preferable. The nonionic surfactant is not particularly limited, and a fluorine-based surfactant or silicon-based surfactant is further preferably used.

The amount of the surfactant to be used is usually about 0.001 to 5% by mass, preferably 0.005 to 2% by mass, further preferably 0.01 to 0.5% by mass based on the total amount of the developer.

As the development method, there can be applied, for example, a method of dipping the substrate in a bath filled with the developer, for a certain time (dipping method), a method of performing development by raising the developer on the substrate surface by surface tension and leaving it to still stand for a certain time (paddle method), a method of spraying the developer on the substrate surface (spray method), or a method of continuously applying the developer while scanning a developer application nozzle at a certain speed on the surface rotating at a certain speed (dynamic dispense method). The time for performing development of the pattern is not particularly limited and is preferably 10 seconds to 90 seconds.

A step of stopping development while replacing the solvent with other solvent may also be performed after the development step.

Furthermore, a step of washing with a rinse liquid including an organic solvent can be included after the development step. The rinse liquid for use in the rinse step after development is not particularly limited as long as the rinse liquid does not dissolve a resist pattern cured by crosslinking, and a solution including a general organic solvent, or water can be used. As the rinse liquid, a rinse liquid that contains at least one organic solvent selected from a hydrocarbon-based solvent, a ketone-based solvent, an ester-based solvent, an alcohol-based solvent, an amide-based solvent and an ether-based solvent is preferably used. More preferably, a step of washing with a rinse liquid containing at least one organic solvent selected from the group consisting of a ketone-based solvent, an ester-based solvent, an alcohol-based solvent and an amide-based solvent is performed after development. Further preferably, a step of washing with a rinse liquid containing an alcohol-based solvent or an ester-based solvent is performed after development. Furthermore preferably, a step of washing with a rinse liquid containing a monohydric alcohol is performed after development. Particularly preferably, a step of washing with a rinse liquid containing a monohydric alcohol having 5 or more carbon atoms is performed after development. The time for performing rinse of the pattern is not particularly limited and is preferably 10 seconds to 90 seconds.

The monohydric alcohol for use in the rinse step after development is not particularly limited and examples include straight, branched and cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol or the like can be used. Particularly preferably, 1-hexanol, 2-hexanol, 4-methyl-2-pentanol, 1-pentanol, 3-methyl-1-butanol or the like can be used as the monohydric alcohol having 5 or more carbon atoms.

The above respective components can be used as a mixture of a plurality thereof, or may be used as a mixture with an organic solvent other than the above organic solvents.

The water content in the rinse liquid is particularly limited, and is preferably 10% by mass or less, more preferably 5% by mass or less, particularly preferably 3% by mass or less. The water content can be 10% by mass or less to thereby allow better development property to be achieved.

The vapor pressure of the rinse liquid to be used after development is preferably 0.05 kPa or more and 5 kPa or less, more preferably 0.1 kPa or more and 5 kPa or less, further preferably 0.12 kPa or more and 3 kPa or less at 20° C. The vapor pressure of the rinse liquid is 0.05 kPa or more and 5 kPa or less to thereby enhance temperature uniformity in the wafer surface and also more suppress swelling due to penetration of the rinse liquid, resulting in an improvement in dimensional uniformity in the wafer surface.

The rinse liquid, to which a surfactant is added in a proper amount, can also be used.

In the rinse step, the wafer subjected to development is subjected to a washing treatment using the rinse liquid including the organic solvent. The washing treatment method is not particularly limited, and there can be applied, for example, a method of continuously applying the rinse liquid on the substrate rotating at a certain speed (rotary coating method), a method of dipping the substrate in a bath filled with the rinse liquid, for a certain time (dipping method) or a method of spraying the rinse liquid on the substrate surface (spray method). Preferably, the washing treatment is performed by the rotary coating method, among the above, to rotate the substrate at a number of rotations of 2000 rpm to 4000 rpm, removing the rinse liquid from the substrate.

After formation of the resist pattern, etching is made to thereby provide a pattern wiring substrate. The etching method can be performed by a known method such as dry etching in which a plasma gas is used, and wet etching by an alkali solution, a cupric chloride solution, a ferric chloride solution or the like.

After formation of the resist pattern, plating can also be performed. The plating method is, for example, copper plating, solder plating, nickel-plating or gold plating.

The resist pattern remaining after etching can be stripped by an organic solvent, or an alkali aqueous solution stronger in alkalinity than the alkali aqueous solution used in development. Examples of the organic solvent include PGMEA (propylene glycol monomethyl ether acetate), PGME (propylene glycol monomethyl ether) and EL (ethyl lactate), and examples of the strong alkaline aqueous solution include an aqueous 1 to 20% by mass sodium hydroxide solution and an aqueous 1 to 20% by mass potassium hydroxide solution. Examples of the stripping method include a dipping method and a spray system. The wiring substrate, where the resist pattern is formed, may be a multilayer wiring substrate and may have a small diameter through-hole.

The wiring substrate obtained in the present invention can also be formed by a method in which, after formation of the resist pattern, a metal is deposited in vacuum and thereafter the resist pattern is dissolved in a solution, namely, a liftoff method.

### EXAMPLES

Hereinafter, embodiments of the present invention are more specifically described with reference to Examples, but the present invention is not limited to these Examples.

### Example 1

### Synthesis of Poly(tBCRA[4]-co-ADB)

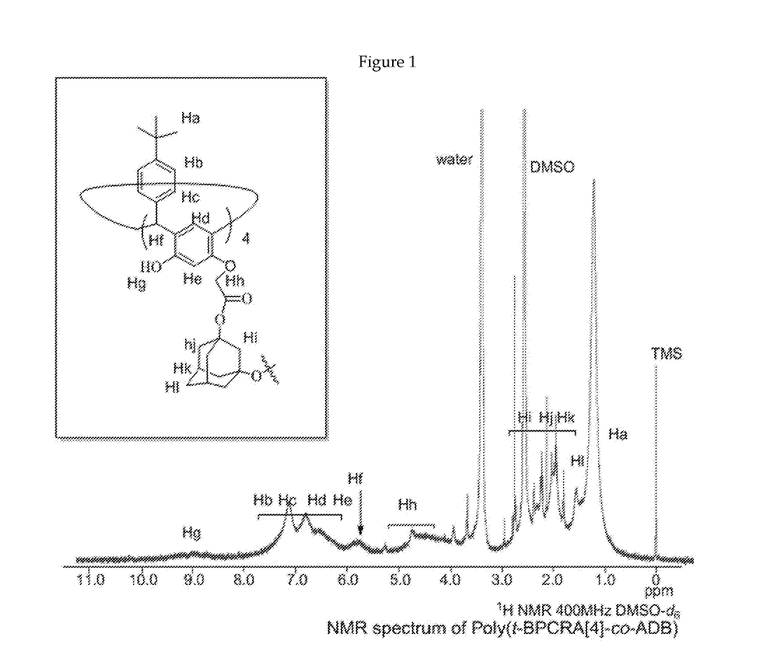

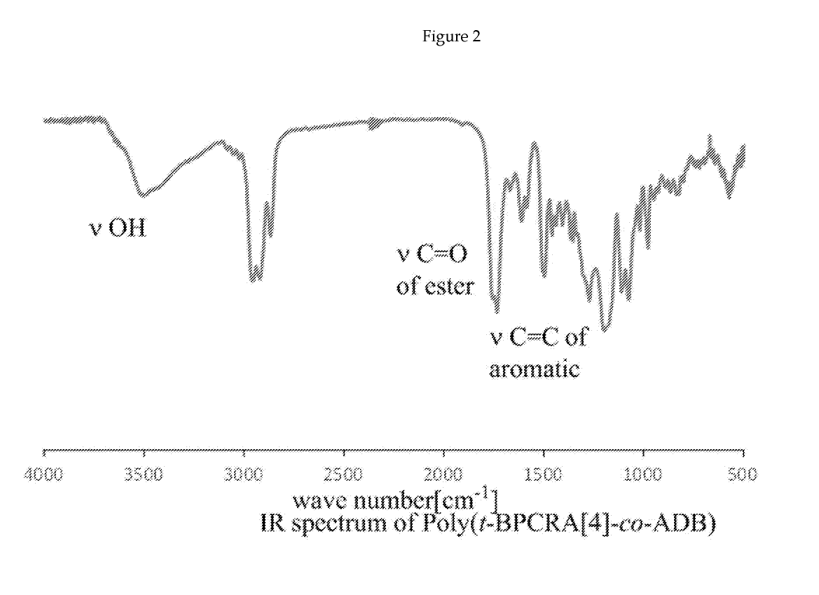

A 200-ml eggplant flask was used to dissolve 1.02 g (1.0 mmol) of C-t-butylphenyl[4]calixresorcinarene (hereinafter, referred to as “tBCRA[4]”) in 20 ml of N-methylpyrrolidone. Next, 0.8 g (0.25 mmol) of tetrabutylammonium bromide and 0.288 g (12 mmol) of sodium hydride were added and stirred at 80° C. for 2 hours. Thereafter, 1.63 g (4.0 mmol) of bromoacetic acid-2-methyladamantane-2-yl was added and reacted in conditions of 80° C. and 48 hours. After completion of the reaction, the resultant was subjected to reprecipitation by an aqueous 1N-HCl solution and then filtrated, and thereafter washed with water to provide a solid. Next, the resulting solid was dissolved in ethyl acetate and purified by column chromatography. The structure of the resulting solid (compound) was identified by ¹H-NMR (Nuclear Magnetic Resonance) and IR (Infrared absorption spectrometry). FIG. 1 is a diagram illustrating a ¹H-NMR spectrum of the compound synthesized in Synthesis Example 1. FIG. 2 is a diagram illustrating an IR spectrum of the compound synthesized in Synthesis Example 1.

The structure was identified, and as a result, it was confirmed that the resulting compound was a mixture including a compound (condensation reaction product of C-t-butylphenyl[4]calixresorcinarene and bromoacetic acid-2-methyladamantane-2-yl (hereinafter, referred to as “Poly(tBCRA[4]-co-ADB)”)) in which, in the general formula (1), R¹ represented hydrogen, R² represented a bonding group derived from bromoacetic acid-2-methyladamantane-2-yl, R³ represented a t-butylphenyl group and m₁+n₁=m₂+n₂=4 was satisfied. It was also confirmed that the following compound was included in the mixture. Poly(tBCRA[4]-co-ADB) has a tetramer structure as follows.

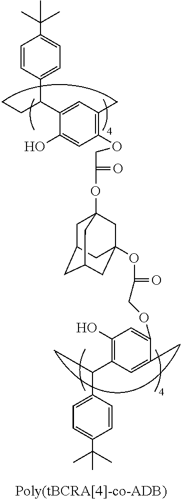

The number average molecular weight (Mn) and the molecular weight distribution (Mw/Mn) of the resulting solid (compound) were calculated by SEC (Size Exclusion Chromatography) measurement where dimethylformamide was used for an eluent. The rate of introduction of adamantane to the compound was calculated from the integrated intensity ratio of the signal due to the aromatic proton of tBCRA[4] and the signal due to the adamantyl ester proton in¹H-NMR.

It was found from the measurement results that, with respect to Poly(tBCRA[4]-co-ADB), the amount recovered was 1.1 g, the yield was 49%, the Mn was 3360 (Mw/Mn=1.54), the reaction rate of the hydroxy group of tBCRA[4] was 70%, the Tdi was 216° C., and the Td 5% (5% thermal mass loss temperature) was 280° C.

### Example 2

### Synthesis of Poly(CCRA[4]-co-ADB)

The same manner as in Example 1 was performed except that tBCRA[4] was changed to 4-C-cyclohexylphenyl[4]calixresorcinarene (hereinafter, referred to as “CCRA[4]”), and it was confirmed that a mixture including a compound (condensation reaction product of 4-C-cyclohexylphenyl[4]calixresorcinarene and bromoacetic acid-2-methyladamantane-2-yl (hereinafter, referred to as “Poly(CCRA[4]-co-ADB)”)) in which, in the general formula (1), R¹ represented hydrogen, R² represented a bonding group derived from bromoacetic acid-2-methyladamantane-2-yl, R³ represented a 4-C-cyclohexylphenyl group, and m₁+n₁=m₂+n₂=4 was satisfied was obtained. It was also confirmed that the following compound was included in the mixture. Poly(CCRA[4]-co-ADB) has a tetramer structure as follows.

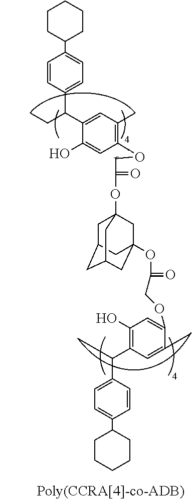

### Example 3

### Synthesis of Poly(iPCRA[4]-co-ADB)

The same manner as in Example 1 was performed except that tBCRA[4] was changed to 4-C-i-propylphenyl[4]calixresorcinarene (hereinafter, referred to as “iPCRA[4]”), and it was confirmed that a mixture including a compound (condensation reaction product of 4-C-i-propylphenyl[4]calixresorcinarene and bromoacetic acid-2-methyladamantane-2-yl (hereinafter, referred to as “Poly(iPCRA[4]-co-ADB)”)) in which, in the general formula (1), R¹ represented hydrogen, R² represented a bonding group derived from bromoacetic acid-2-methyladamantane-2-yl, R³ represented a 4-C-i-propylphenyl group, and m₁+n₁=m₂+n₂=4 was satisfied was obtained. It was also confirmed that the following compound was included in the mixture. Poly(iPCRA[4]-co-ADB) has a tetramer structure as follows.

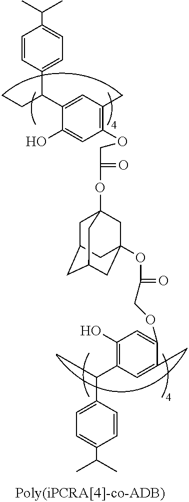

### Example 4

### Synthesis of Poly(BCRA[4]-co-mXG)

The same manner as in Example 1 was performed except that bromoacetic acid-2-methyladamantane-2-yl was changed to 1,3-bis[(chloromethoxy)methyl]benzene (hereinafter, referred to as “mXG”), and it was confirmed that a mixture including a compound (condensation reaction product of 4-t-butylphenylcalix[4]arene and 1,3-bis[(chloromethoxy)methyl]benzene (hereinafter, referred to as “Poly(BCRA[4]-co-mXG”)) in which, in the general formula (1), R¹ represented hydrogen, R² represented a bonding group derived from 1,3-bis[(chloromethoxy)methyl]benzene, R³ represented a t-butylphenyl group, and m₁+n₁=m₂+n₂=4 was satisfied was obtained. It was also confirmed that the following compound was included in the mixture. Poly(BCRA[4]-co-mXG) has a tetramer structure as follows.

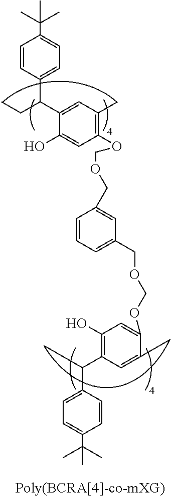

### <Preparation and Evaluation of Radiation Sensitive Composition>

### (Patterning Test)

Components shown in Table 1 below were blended to provide a uniform solution. Thereafter, the solution was filtrated by a Teflon (registered trademark) membrane filter having a pore diameter of 0.1 μm to prepare a radiation sensitive composition. The resulting radiation sensitive composition was evaluated as follows. The results are shown in Table 2.

### (1) Evaluation of Sensitivity

A clean silicon wafer was coated with the radiation sensitive composition (resist) by rotary coating, and thereafter baked before exposure (prebaked) in an oven to form a resist film having a thickness of 60 nm. An electron beam exposure apparatus (manufactured by Elionix Inc., product name: ELS-7500,) was used to irradiate the resulting resist film with an electron beam, with the line-and-space being set to 1:1 and the interval being set to 100 nm. After irradiation with an electron beam, the resist film was heated at a predetermined temperature (PEB shown in Table 2 below) for 90 seconds, and subjected to development in THF for 60 seconds. Thereafter, the resultant was dried to form a resist pattern. The line-and-space of the resulting resist pattern was observed by a scanning electron microscope (manufactured by Hitachi High-Technologies Corporation, product name: S-4800), and the sensitivity of the resulting polymer compound was evaluated according to the following evaluation criteria based on the amount of dose (μC/cm²).

### (Evaluation Criteria)

A: Amount of dose≦30 μC/cm² (excellent sensitivity)
B: 30 μC/cm²<Amount of dose≦800 μC/cm² (good sensitivity)
C: 800 μC/cm²<Amount of dose (poor sensitivity)

### (2) Evaluation of Line Edge Roughness (LER)

A resist pattern with an interval of 100 nm and a line-and-space of 1:1 was produced by the same procedure as in (1) Evaluation of sensitivity above. The distance between the edge and the reference line was measured at any 300 points of the pattern with an interval of 100 nm and a line-and-space of 1:1 in the longitudinal direction (0.75 μm) by use of Hitachi Semiconductor SEM, terminal PC and V5 off-line measuring software (manufactured by Hitachi Science Systems, Ltd.). The standard deviation (3σ) was calculated from the measurement results, and the LER of the pattern was evaluated according to the following evaluation criteria.

### (Evaluation Criteria)

A: LER (3σ)≦3.5 nm (good LER)
C: 3.5 nm<LER (3σ) (not good LER)

### (3) Evaluation of Pattern Collapse

A resist pattern with an interval of 30 nm and a line-and-space of 1:1 was formed in an area of 1 μm□ by the same procedure as in (1) Evaluation of sensitivity above. The resulting line-and-space was observed by a scanning electron microscope (manufactured by Hitachi High-Technologies Corporation, product name: S-4800), and pattern collapse was evaluated according to the following evaluation criteria.

### (Evaluation Criteria)

A: No pattern collapse
C: Partial pattern collapse

It was confirmed from the above patterning test results that the radiation sensitive composition using the polymer compound of the present embodiment was good in sensitivity and LER, and enabled to suppress fine pattern collapse.

TABLE 1

| | | | Acid | |
|---|---|---|---|---|
| | | Acid | diffusion | |
| | Polymer compound | generator | inhibitor | Solvent |
| Example 1 | Poly(tBCRA[4]-co-ADB) | P-1 | Q-1 | S-1 |
| | 1.00 g | 0.3 g | 0.03 g | 30.0 g |
| Example 2 | Poly(CCRA[4]-co-ADB) | P-1 | Q-1 | S-1 |
| | 1.00 g | 0.3 g | 0.03 g | 30.0 g |
| Example 3 | Poly(iPCRA[4]-co-ADB) | P-1 | Q-1 | S-1 |
| | 1.00 g | 0.3 g | 0.03 g | 30.0 g |
| Example 4 | Poly(BCRA[4]-co-mXG) | P-1 | Q-1 | S-1 |
| | 1.00 g | 0.3 g | 0.03 g | 30.0 g |

In Table 1 above, the acid generator, the acid diffusion inhibitor and the solvent are as follows.

### (Acid Generator)

P-1: Triphenylbenzenesulfonium trifluoromethanesulfonate (Midori Kagaku Co., Ltd.)

### (Acid Diffusion Inhibitor)

### Q-1: Trioctylamine (Tokyo Chemical Industry Co., Ltd.)

### (Solvent)

S-1: Propylene glycol monomethyl ether (Tokyo Chemical Industry Co., Ltd.)

TABLE 2

| | PEB | Sensitivity | | |
|---|---|---|---|---|
| | (° C.) | (μC/cm²) | LER (3σ) | Pattern collapse |
| Example 1 | 170 | B | A | A |
| Example 2 | 170 | B | A | A |
| Example 3 | 170 | B | A | A |
| Example 4 | 170 | B | A | A |

PEB: Temperature in heating after irradiation with electron beam

The polymer compound of the present invention can be suitably used in, for example, an acid amplified radiation sensitive composition, and a resist pattern forming method using the composition.

1. A polymer compound comprising a unit structure represented by the following general formula (1): 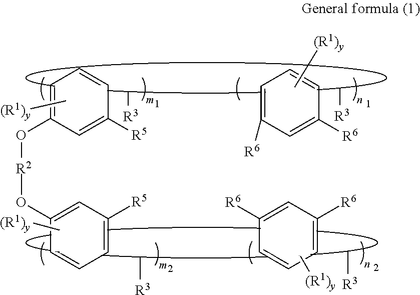
wherein in the general formula (1), m₁ represents an integer of 1 to 8, n₁ represents an integer of 0 to 7, m₁+n₁ equals an integer of 4 to 8, m₂ represents an integer of 1 to 8, n₂ represents an integer of 0 to 7, m₂+n₂ equals an integer of 4 to 8, each y independently represents an integer of 0 to 2, each R¹ independently represents a hydroxy group; a substituted or unsubstituted, straight, branched or cyclic alkyl group having 1 to 20 carbon atoms, 3 to 20 carbon atoms or 3 to 20 carbon atoms, respectively; a substituted or unsubstituted aryl group having 6 to 20 carbon atoms; or a halogen atom, each R³ independently represents a hydrogen atom, a substituted or unsubstituted, straight, branched or cyclic alkyl group having 1 to 20 carbon atoms, 3 to 20 carbon atoms or 3 to 20 carbon atoms, respectively; or a substituted or unsubstituted aryl group having 6 to 20 carbon atoms, each R² independently represents any structure represented by the following general formula (2), provided that at least one R² has an acid-dissociable site, R⁵ represents a hydroxy group, —O—R²—O—* (* represents a binding site of the unit structure) or —O—R²—O—R⁵⁵ (R⁵⁵ represents other R⁵ in the general formula (1)), and R⁶ represents a hydroxy group or —O—R²—O—* (* represents a binding site of the unit structure); 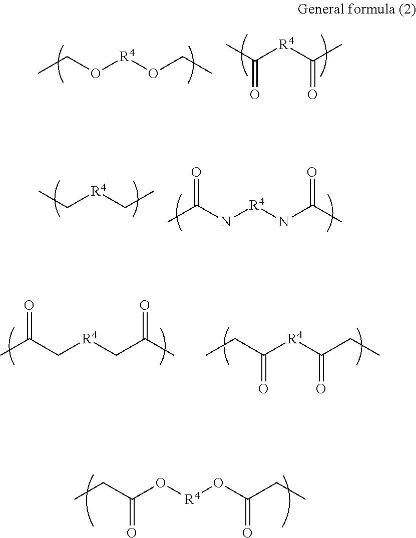
wherein in the general formula (2), R⁴ represents a substituted or unsubstituted straight, branched or cyclic alkylene group having 1 to 20 carbon atoms, 3 to 20 carbon atoms or 3 to 20 carbon atoms, respectively; or a substituted or unsubstituted arylene group having 6 to 20 carbon atoms.

2. The polymer compound according to claim 1, wherein in the general formula (1), R³ represents a substituted or unsubstituted, straight, branched or cyclic alkyl group having 1 to 10 carbon atoms, 3 to 20 carbon atoms or 3 to 20 carbon atoms, respectively; or a substituted or unsubstituted aryl group having 6 to 10 carbon atoms.

3. A radiation sensitive composition comprising the polymer compound according to claim 1.

4. The radiation sensitive composition according to claim 3, further comprising a solvent.

5. A pattern forming method comprising
forming a film on a substrate by use of the radiation sensitive composition according to claim 3,
exposing the film, and
developing the film exposed to form a pattern.

6. A radiation sensitive composition comprising the polymer compound according to claim 2.

7. A pattern forming method comprising
forming a film on a substrate by use of the radiation sensitive composition according to claim 4,
exposing the film, and
developing the film exposed to form a pattern.
